(19) United States
(12) Patent Application Publication
(10) Pub. No.: US 2012/0071001 A1
(43) Pub. Date: Mar. 22, 2012

(54) VAPORIZING AND FEED APPARATUS AND VAPORIZING AND FEED METHOD

(75) Inventor: Hiroyuki ODE, Tokyo (JP)

(73) Assignee: ELPIDA MEMORY, INC., Tokyo (JP)

(21) Appl. No.: 13/232,077

(22) Filed: Sep. 14, 2011

(30) Foreign Application Priority Data
Sep. 17, 2010 (JP) 2010-209243
Sep. 28, 2010 (JP) 2010-217284
Sep. 29, 2010 (JP) 2010-218133

(51) Int. Cl. H01L 21/31; C23C 16/448

(52) U.S. Cl. 438/758; 118/726; 257/E21.24

(57) ABSTRACT

A vaporizing and feed apparatus for vaporizing and feeding a solid film-forming raw material comprises a supercritical fluid feeding part for producing and feeding a supercritical fluid, a supercritical fluid adjusting part for dissolving the solid film-forming raw material in the supercritical fluid by bringing the supercritical fluid fed from the supercritical fluid feeding part into contact with the solid film-forming raw material, and a vaporizing part for phase-transitioning the supercritical fluid having the dissolved solid film-forming raw material to a gas, the solid film-forming raw material thereby being deposited in the gas, and for vaporizing the deposited solid film-forming raw material.

### BACKGROUND OF THE INVENTION

1. Field of the Invention

The present invention relates to a vaporizing and feed apparatus and a vaporizing and feed method.

2. Description of the Related Art

In the manufacture of a semiconductor apparatus, a film-forming method such as a Chemical Vapor Deposition (CVD) method or an Atomic Layer Deposition (ALD) method is used in order to form a thin film having a prescribed function on a substrate surface subjected to microfabrication.

On the other hand, in order to meet the demand for higher performance of the semiconductor apparatus, a thin film formed using a solid state raw material having a low vapor pressure (i.e. using a solid film-forming raw material (FFRM)) is required, for example, as in an insulating film having a high dielectric constant. Thus, it is necessary to establish a forming method therefor.

When a film is formed using the solid FFRM, it is necessary to vaporize the raw material and introduce the vaporized raw material into a film-forming chamber for causing a film-forming reaction. For this purpose, the following methods are known:

(1) The solid FFRM is sublimated by heating in a storage container. The sublimated raw material is mixed with other career gas, and the mixture is introduced to the film-forming chamber.

(2) The solid FFRM is dissolved in a solvent (for example, tetrahydrofuran (THF)), and the solution is vaporized through a vaporizer. Alternatively, the solution is vaporized by passing a carrier gas through the solution. The raw material thus vaporized is introduced to the film-forming chamber.

However, a problem that is pointed out is that it is difficult to widely apply each of the methods as a mass production technique. That is, in the above-mentioned method (1), the amount of solid FFRM vaporized is unstable due to a change in the surface area of the solid FFRM caused by the sublimation. In addition, as the sublimation proceeds, the surface state of the solid FFRM is changed to gradually decrease the amount vaporized. Thereby, it becomes difficult to secure the industrially sufficient amount of the raw material fed.

In the above-mentioned method (2), a large amount of solvent is also introduced to the film-forming chamber simultaneously with the FFRM, which causes impurities remaining in the film. Therefore, it becomes difficult to obtain desired film characteristics. In addition, the solvent containing the FFRM may not be sufficiently vaporized, and the solvent may be sent to the film-forming chamber in a mist state. In that case, particles are generated, which lead to the reduction of the manufacturing yield.

Then, a method using a supercritical fluid is proposed as the method for introducing the FFRM into the film-forming chamber aside from such a method.

JP2003-213425A describes a method for dissolving a FFRM in a supercritical fluid and spraying the supercritical fluid on a substrate from a nozzle to form a film. JP2009-094276A describes a column type apparatus previously proposed by the inventor of the present invention and used when a solid FFRM is dissolved in a supercritical fluid.

However, in the method described in JP2003-213425A, locally deposited nuclei are apt to be formed on the substrate, which complicates the formation of a uniform thin film. Thereby, the method cannot be applied to the solid FFRM.

On the other hand, even the solid FFRM can be easily dissolved in the supercritical fluid using the column type apparatus described in JP2009-094276A. Thereby, the supercritical fluid containing the solid FFRM can be carried to the film-forming chamber. That is, the solid FFRM can be stably fed to the film-forming chamber. However, even if the solid FFRM dissolved in the supercritical fluid can be stably fed to the film-forming chamber, at present, a method for forming a uniform film from the solid FFRM having such a state has not been established.

In the meantime, the conventional CVD method and ALD method are preferably used as the method for forming the uniform thin film. Therefore, the solid FFRM dissolved in the supercritical fluid is required to be treated to a form capable of being used for film formation by such a method (i.e. to a vaporized state), to be stably fed to the film-forming chamber.

### SUMMARY OF THE INVENTION

In one embodiment, there is provided a vaporizing and feed apparatus for vaporizing and feeding a solid film-forming raw material. The apparatus comprises a supercritical fluid feeding part for producing and feeding a supercritical fluid, a supercritical fluid adjusting part for dissolving the solid film-forming raw material in the supercritical fluid by bringing the supercritical fluid fed from the supercritical fluid feeding part into contact with the solid film-forming raw material, and a vaporizing part for phase-transitioning the supercritical fluid having the dissolved solid film-forming raw material to a gas, the solid film-forming raw material thereby being deposited in the gas, and for vaporizing the deposited solid film-forming raw material.

In such a vaporizing and feed apparatus, when the supercritical fluid is phase-transitioned to the gas, the solid film-forming raw material dissolved in the supercritical fluid is deposited as fine particles each having a large surface area and high heat conductivity. Thus, by changing the solid film-forming raw material to the fine particles and vaporizing the fine particles, the stable feed of the solid film-forming raw material capable of being used for the film-forming method by the conventional CVD method and ALD method is possible.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic view showing the constitution of a film-forming apparatus provided with a vaporizing and feed apparatus of the present invention;

FIG. 2 is a schematic view showing the constitution of a vaporizing and feed apparatus according to a first embodiment of the present invention;

FIG. 3 is a schematic view showing the constitution of a vaporizing part of the vaporizing and feed apparatus shown in FIG. 2;

FIG. 4 is a schematic view showing the constitution of a vaporizing and feed apparatus according to a second embodiment of the present invention;

FIG. 5A is a schematic view showing the constitution of a dissolving column of the vaporizing and feed apparatus shown in FIG. 4;

FIG. 5B is an enlarged view of a region surrounded by a circle in FIG. 5A before a supercritical fluid is introduced;

FIG. 5C is an enlarged view of a region surrounded by a circle in FIG. 5A after a supercritical fluid has been introduced;

FIG. 6 is a view schematically showing an example of the constitution of a film-forming apparatus according to a third embodiment of the present invention;

FIG. 7 is a sectional view schematically showing the structure of a stage;

FIG. 8 is a view showing an example of the relationship between film-forming time and a film thickness when an oxide silicon film is formed;

FIG. 9A is a view schematically showing the flow of a supercritical fluid in a film-forming step of a film-forming method according to the third embodiment of the present invention;

FIG. 9B is a view schematically showing the flow of a supercritical fluid in a rapid pressure reduction step of the film-forming method according to the third embodiment of the present invention;

FIG. 9C is a view schematically showing the flow of a supercritical fluid in a raw material discharging step of the film-forming method according to the third embodiment of the present invention;

FIG. 10 is a view showing the calculated values of pressure change before and after opening a valve between a film-forming chamber and a pressure release chamber;

FIG. 11A is a view showing change in a raw material concentration and a film-forming rate in a film-forming chamber in a film-forming method of a related technique;

FIG. 11B is a view showing change in a raw material concentration and a film-forming rate in a film-forming chamber in the film-forming method according to the third embodiment of the present invention;

FIG. 12A is a view showing a constitution in which a film-forming chamber and a recovery tank are connected through a back pressure adjuster;

FIG. 12B is a view showing a constitution in which the film-forming chamber and the recovery tank are connected through a pressure release chamber and a back pressure adjuster;

FIG. 13 is a view schematically showing a modification of the film-forming chamber according to the third embodiment of the present invention;

FIG. 14 is a plan view showing the schematic constitution of a film-forming apparatus according to a fourth embodiment of the present invention;

FIG. 15 is a sectional view showing the constitution of the inside of a film-forming raw material deposition chamber shown in FIG. 1;

FIGS. 16A to 16C are sectional views of a semiconductor substrate for describing a film-forming method according to the fourth embodiment of the present invention;

FIG. 17 is a schematic pressure-temperature phase diagram for carbon dioxide;

FIG. 18 is a sectional view of a raw material deposition chamber and a heater for heating a substrate which are provided in a film-forming apparatus according to a fifth embodiment of the present invention;

FIG. 19 is a view showing a result obtained by measuring the change in the density of carbon dioxide when the pressure of the carbon dioxide is changed;

FIG. 20 is a view showing a result obtained by measuring the change in the density of carbon dioxide when the temperature of the carbon dioxide is changed; and

FIG. 21 is a sectional view showing the schematic inside constitution of a raw material deposition chamber provided in a film-forming apparatus according to a comparative example.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

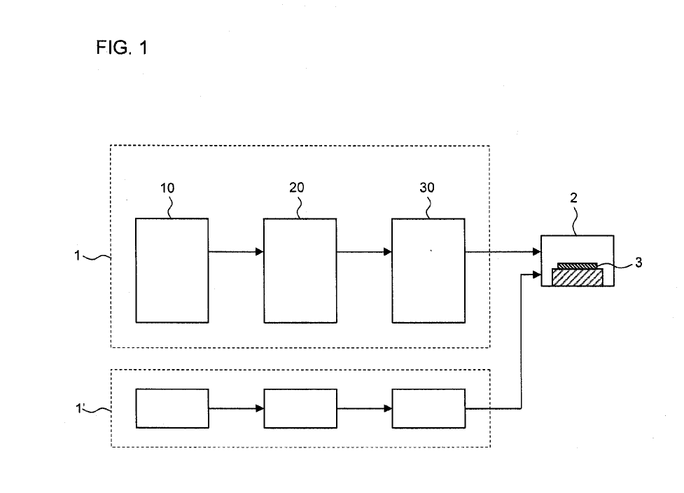

FIG. 1 is a schematic view showing the constitution of a film-forming apparatus provided with a vaporizing and feed apparatus of the present invention.

Vaporizing and feed apparatus 1 of the present invention includes supercritical fluid feeding part 10, supercritical fluid adjusting part 20 and vaporizing part 30. These are connected through metal pipes.

A solid film-forming raw material (FFRM) vaporized in vaporizing and feed apparatus 1 is fed into film-forming chamber 2 in which semiconductor substrate 3 is set. At this time, a supercritical fluid phase-transitioned to a gas state is used as a career gas. In film-forming chamber 2, a film can be formed using a usual ALD method and CVD method. Either film-forming method can be selected according to desired film characteristics.

In the film-forming apparatus shown in FIG. 1, another vaporizing and feed apparatus 1′ is further provided so that two kinds of FFRMs can be vaporized and fed to film-forming chamber 2. Vaporizing and feed apparatus 1′ has the same constitution as that of vaporizing and feed apparatus 1 of the present invention described above, and thereby the solid FFRM can be vaporized to be fed to film-forming chamber 2. Alternatively, when a liquid FFRM is used, vaporizing and feed apparatus 1′ may be a conventional vaporizing and feed apparatus. When three kinds or more of FFRMs are used, yet another vaporizing and feed apparatus can be provided according to the number of the FFRMs to be used. In that case, the vaporizing and feed apparatus of the present invention can be used for vaporizing and feeding the solid FFRM. Furthermore, although not shown in FIG. 1, film-forming chamber 2 may be provided with a device to feed an oxidant such as oxygen (O₂) or ozone (O₃) according to the kind of a film to be formed.

Although single substrate type film-forming chamber 2 is exemplified in FIG. 1, the film-forming chamber used with the vaporizing and feed apparatus of the present invention may be a batch type film-forming chamber capable of simultaneously forming a film on a plurality of semiconductor substrates. That is, a method for combining a CVD method or an ALD method with a single substrate type or a batch type can be applied to the film-forming method in film-forming chamber 2.

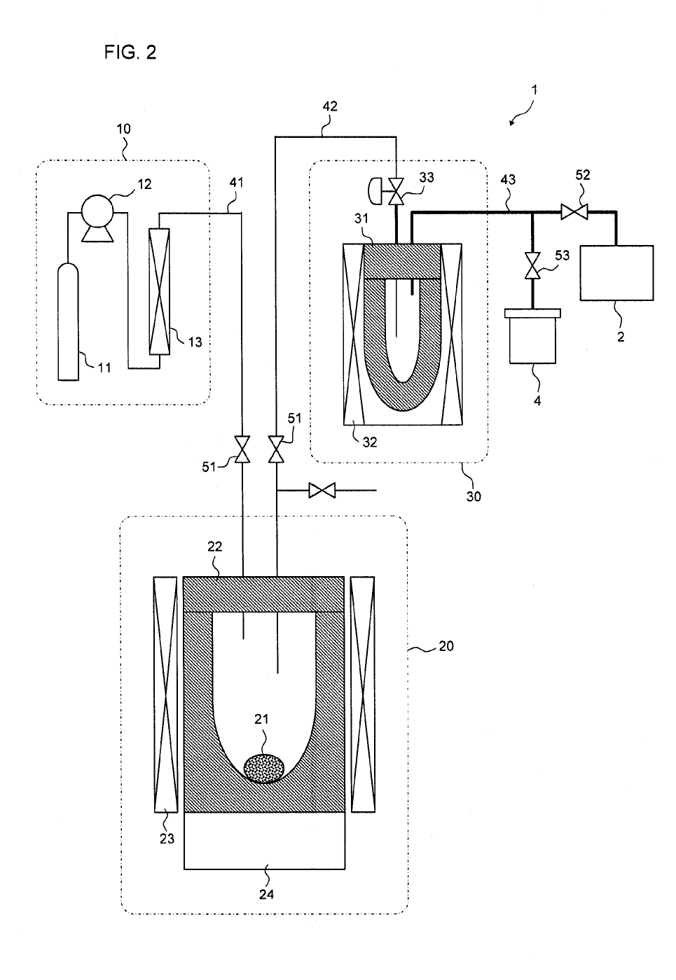

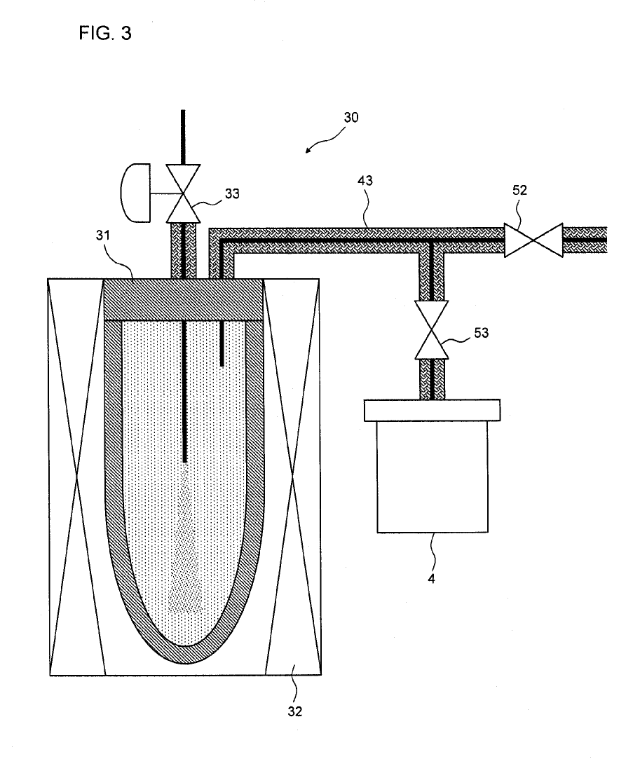

Next, the constitution of the vaporizing and feed apparatus of the present invention will be described in detail with reference to FIGS. 2 and 3.

In the vaporizing and feed apparatus of the present invention, carbon dioxide (CO₂) is suitably used as a supercritical fluid. The carbon dioxide is known to be phase-transitioned to a supercritical state at a temperature equal to or higher than a critical temperature Tc=31.1° C. and a pressure equal to or higher than a critical pressure Pc=7.38 MPa. Hereinafter, in the specification, the vaporizing and feed apparatus of the present invention will be specifically described by giving the example of the case in which the carbon dioxide is used as the supercritical fluid. The supercritical fluid used for the vaporizing and feed apparatus of the present invention is not limited to the carbon dioxide. The supercritical fluid may be another substance existing as a gas in an atmospheric pressure state at a usual room temperature and easily transferable to the supercritical state.

FIG. 2 is a schematic view showing the constitution of a vaporizing and feed apparatus according to a first embodiment of the present invention. FIG. 3 is a schematic view showing the constitution of a vaporizing part of the vaporizing and feed apparatus of this embodiment in detail.

Vaporizing and feed apparatus 1 of this embodiment has supercritical fluid feeding part 10 producing and feeding the supercritical fluid of the carbon dioxide. Supercritical fluid feeding part 10 has cylinder 11 filled with the liquefied carbon dioxide, liquid feed pump 12 pressurizing the liquefied carbon dioxide fed from cylinder 11 to a critical pressure or higher and feeding the pressurized carbon dioxide, and heat exchanger 13 heating the carbon dioxide pressurized by liquid feed pump 12 to a critical temperature or higher. Supercritical fluid feeding part 10 having such a constitution can feed the carbon dioxide passing through heat exchanger 13 as the supercritical fluid.

Furthermore, vaporizing and feed apparatus 1 of this embodiment has supercritical fluid adjusting part 20 to which the supercritical carbon dioxide is fed from critical fluid feeding part 10. As shown by a thin solid line of FIG. 2, supercritical fluid adjusting part 20 and critical fluid feeding part 10 are connected by pipe 41 made of, for example, stainless steel.

Supercritical fluid adjusting part 20 has high-pressure dissolving chamber 22 which accommodates solid FFRM 21 and to which the supercritical fluid is introduced, and heater 23 that is disposed so as to cover the outside of high-pressure dissolving chamber 22 and that heats high-pressure dissolving chamber 22. The inside of high-pressure dissolving chamber 22 can be held at a pressure equal to or higher than the critical pressure and can be held at a temperature equal to or higher than the critical temperature by heater 23 so that the supercritical state of the carbon dioxide can be maintained. Thereby, in supercritical fluid adjusting part 20, solid FFRM 21 can be dissolved in the supercritical fluid by bringing the supercritical fluid into contact with solid FFRM 21 accommodated in high-pressure dissolving chamber 22. Stirring mechanism 24 such as a stirrer is provided in supercritical fluid adjusting part 20 in order to efficiently dissolve solid FFRM 21 in the supercritical fluid. Stirring mechanism 24 stirs the mixture of the supercritical carbon dioxide and solid FFRM 21 in high-pressure dissolving chamber 22.

Furthermore, vaporizing and feed apparatus 1 of this embodiment has vaporizing part 30 to which the supercritical fluid having the dissolved solid FFRM is fed from supercritical fluid adjusting part 20. Vaporizing part 30 and supercritical fluid adjusting part 20 are connected by, for example, stainless steel pipe 42 as shown by a thin solid line of FIG. 2, as in the connection between supercritical fluid adjusting part 20 and supercritical fluid feeding part 10.

Vaporizing part 30 has vaporizing chamber 31 to which the supercritical fluid having the dissolved solid FFRM is introduced, and heater (heating device) 32 that is disposed so as to cover the outside of vaporizing chamber 31 and that heats the inside of vaporizing chamber 31 to the vapor temperature or more of the solid FFRM. Vaporizing part 30 has back pressure adjuster (pressure adjusting device) 33 that is provided on pipe 42 between supercritical fluid adjusting part 20 and vaporizing part 30, and that is capable of adjusting the pressure of the supercritical fluid introduced to the vaporizing chamber 31.

Back pressure adjuster 33 is set so that the inside of vaporizing chamber 31 is held at a pressure lower than the critical pressure of the supercritical fluid when the supercritical fluid is introduced to vaporizing chamber 31. In vaporizing part 30, the supercritical fluid having the dissolved solid FFRM can be phase-transitioned to a gas by such a constitution. As a result, the solid FFRM can be deposited in the gas, and the deposited solid FFRM can be vaporized. This process will be described in detail hereinafter.

Film-forming chamber 2 described above and recovery container 4 for recovering an excess FFRM are connected to the rear stage of vaporizing part 30 through, for example, a stainless steel pipe 43. As shown by the thick solid line of FIG. 2, pipe 43 between vaporizing part 30 and film-forming chamber 2 and a part of pipe 42 (the downstream side of back pressure adjuster 33) between supercritical fluid adjusting part 20 and vaporizing part 30 are held at a prescribed temperature equal to or higher than a room temperature, in order to maintain the vaporizing state of a substance moving in the pipes.

Valve 51 for adjusting the flow volume of the supercritical fluid passing through the inside of each of pipes 41 and 42 is provided on each of pipes 41 and 42.

Next, a vaporizing and feed method for feeding the solid FFRM using the vaporizing and feed apparatus of this embodiment will be described again with reference to FIGS. 2 and 3.

For example, when a strontium titanate film (SrTiO₃) is formed on a semiconductor substrate in the film-forming chamber, two kinds of solid FFRMs are used. That is, Sr(THD)₂ and Ti(MPD)(THD)₂ which are solid raw materials are used as Sr and Ti feeding sources. In such a case, two vaporizing and feed apparatuses of this embodiment are provided in an actual film-forming apparatus. Furthermore, a device for feeding an oxidant such as ozone (O₃) is provided.

### (Step of Preparing Solid FFRM)

First, the solid FFRM is accommodated in high-pressure dissolving chamber 22. At this time, the inside of high-pressure dissolving chamber 22 is held in a closed state.

### (Step of Producing Supercritical Fluid)

Next, the liquefied carbon dioxide with which cylinder 11 is filled is fed to liquid feed pump 12, where the liquefied carbon dioxide is pressurized to the critical pressure or higher. The carbon dioxide pressurized by liquid feed pump 12 is sent to heat exchanger 13, where the carbon dioxide is heated to the critical temperature or higher. Thus, the supercritical fluid of the carbon dioxide is produced in supercritical fluid feeding part 10. The supercritical carbon dioxide is fed to subsequent supercritical fluid adjusting part 20 through pipe 41.

### (Step of Dissolving Solid FFRM)

The supercritical fluid fed to supercritical fluid adjusting part 20 is introduced to high-pressure dissolving chamber 22 in which solid FFRM 21 is previously accommodated. At this time, high-pressure dissolving chamber 22 is heated by heater 23. Therefore, the inside of high-pressure dissolving chamber 22 can be held at a temperature and pressure equal to or higher than the critical point of the supercritical fluid, as described above. Thereby, the supercritical state of the carbon dioxide introduced to high-pressure dissolving chamber 22 is maintained.

The supercritical fluid introduced to high-pressure dissolving chamber 22 is brought into contact with solid FFRM 21, and thereby solid FFRM 21 is dissolved in the supercritical fluid. At this time, solid FFRM 21 and the supercritical fluid are preferably stirred by stirring mechanism 24 such as a stirrer, and thereby solid FFRM 21 can be efficiently dissolved in the supercritical fluid.

A sufficient amount of solid FFRM 21 is preferably accommodated in high-pressure dissolving chamber 22 so that the concentration of the FFRM in the supercritical fluid after dissolving is always a saturated concentration. Therefore, when a film is continuously formed, it is preferable that the FFRM is added to high-pressure dissolving chamber 22 or the FFRM is appropriately exchanged to a new FFRM before the concentration of the FFRM reaches a saturated concentration or lower.

Thus, the supercritical fluid adjusted so as to contain the FFRM is fed to vaporizing part 30 through pipe 42. The flow volume at this time is controlled by liquid feed pump 12 and valves 51 provided on pipes 41 and 42.

### (Step of Vaporizing Solid FFRM)

The pressure of the supercritical fluid having the dissolved solid FFRM is adjusted by passing the supercritical fluid through back pressure adjuster 33. Then, the supercritical fluid is introduced into vaporizing chamber 31 so that the inside of vaporizing chamber 31 is at atmospheric pressure. That is, in this embodiment, the high-pressure supercritical fluid is introduced into vaporizing chamber 31 held at the atmospheric pressure or a pressure lower than the critical pressure of the supercritical fluid.

When the high-pressure supercritical fluid is introduced to vaporizing chamber 31 held at the atmospheric pressure, the high-pressure supercritical fluid is largely expanded and sprayed into vaporizing chamber 31. At this time, the supercritical fluid is momentarily phase-transitioned to a gas state (gaseous state) in which a substance cannot be dissolved with the reduction of pressure. Thereby, the FFRM dissolved in the supercritical fluid is also momentarily deposited. The FFRM just deposited exists in the gas as fine particles without aggregation. Since this fine particle has a larger surface area and higher heat conductivity compared to the original solid state (larger powder, crystal, mass states), the fine particle tends to be efficiently vaporized. In addition, the inside of vaporizing chamber 31 is held in a suitable condition, that is, at the vapor temperature or higher of the solid FFRM, by heater 32. As a result, the solid FFRM deposited as the fine particles is vaporized in vaporizing chamber 31 before interparticle aggregation takes place.

### (Step of Feeding Solid FFRM)

The FFRM thus vaporized is fed to film-forming chamber 2 through pipe 43 heated to a prescribed temperature while the vaporizing state of the FFRM is maintained. At this time, a gaseous supercritical fluid source (a carbon dioxide gas) is used as a career gas.

The introduction of the vaporized FFRM to film-forming chamber 2 is controlled by the switching operation of valves 52 and 53 provided on pipe 43. That is, the vaporized FFRM is introduced to film-forming chamber 2 by opening valve 52 and closing valve 53. The introduction of the FFRM is shut down by closing valve 52 and opening valve 53, and the solid FFRM is recovered to recovery container 4. When a film is formed using the ALD method in film-forming chamber 2, an ALD valve (a diaphragm valve) capable of being opened and closed at high speed is preferably used as valve 52 that is opened during the period when a raw material is introduced.

For example, when a SrTiO₃ film is formed using the ALD method, a Sr raw material (Sr(THD)₂) and a Ti raw material (Ti(MPD)(THD)₂) are sequentially fed to the film-forming chamber using the vaporizing and feed apparatus of this embodiment, and are adsorbed on the semiconductor substrate. The adsorbed FFRM is oxidized by feeding an ozone gas serving as an oxidant. The SrTiO₃ film is formed by repeating the cycle. The SrTiO₃ film thus formed can be applied to a capacitance insulating film or the like constituting the capacitor of a DRAM element.

As described above, in the vaporizing and feed apparatus and vaporizing and feed method of this embodiment, the solid FFRM is dissolved in the supercritical fluid, and then the supercritical fluid is phase-transitioned to a gas, and thereby the solid FFRM can be deposited in the gas. At this time, since the solid FFRM just deposited exists as fine particles having a large surface area and high heat conductivity, the solid FFRM can be stably vaporized. Thereby, the vaporized solid FFRM can be stably fed to the film-forming chamber at a constant speed, and a uniform thin film can be formed using the CVD method or the ALD method in the film-forming chamber as in the case in which a vaporized liquid FFRM is used.

In this embodiment, the supercritical fluid is used when the solid FFRM is vaporized, and it is not necessary to use a solvent such as THF. Thereby, impurities derived from the solvent are not accumulated in the formed film. Furthermore, the solvent is not sent to the film-forming chamber in a mist state, and as a result, the generation of particles can be also suppressed. Since the supercritical fluid is also similarly phase-transitioned to a gas finally, the supercritical fluid is not contained in the formed film as impurities, and does not cause the generation of the particles that are caused by generating mist. Thus, a uniform and high-quality film having prescribed characteristics can be formed.

### Second Embodiment

A dissolving column previously proposed by the inventor of the present invention (in JP2009-094276A) can be also used in place of the high-pressure dissolving chamber shown in FIG. 2.

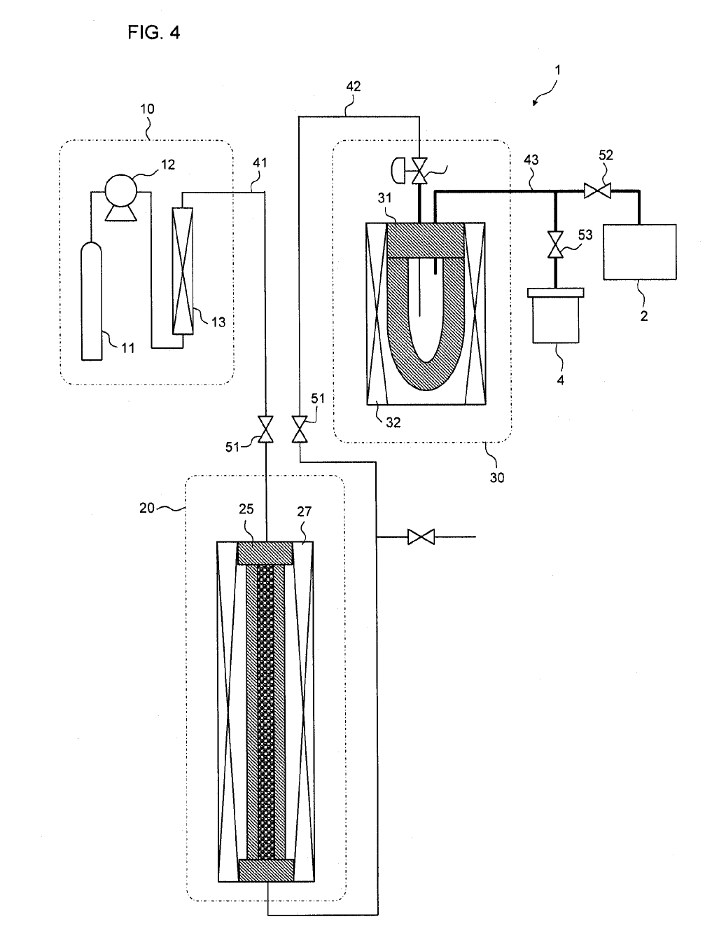

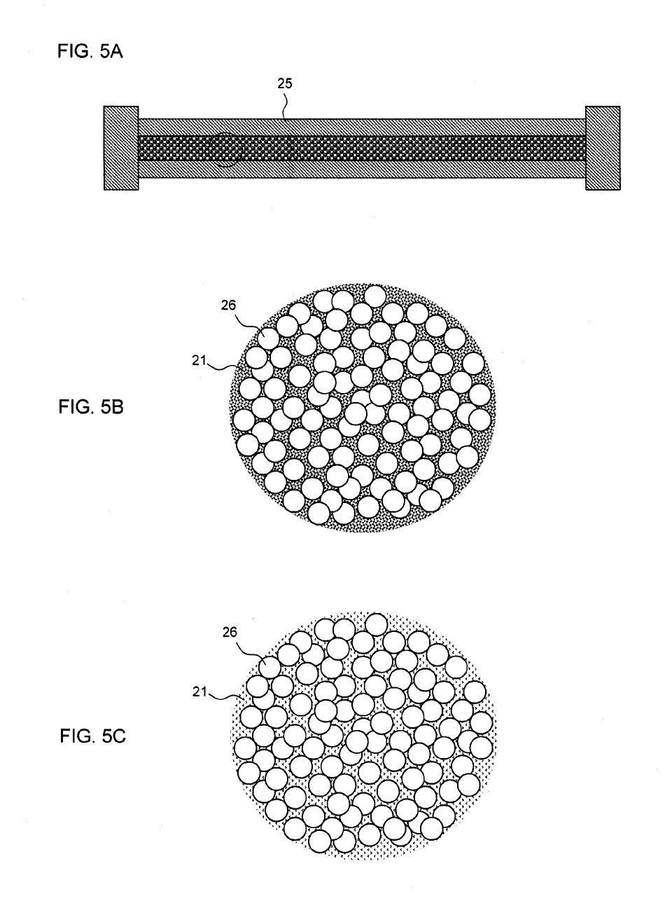

FIG. 4 is a schematic view showing the constitution of a vaporizing and feed apparatus according to a second embodiment of the present invention having the above-mentioned dissolving column. FIG. 5A is a plan view schematically showing the dissolving column of this embodiment. Each of FIGS. 5B and 5C is an enlarged view of a region surrounded by a circle in FIG. 5A. FIG. 5B schematically shows the region before a supercritical fluid is introduced. FIG. 5C schematically shows the region after the supercritical fluid has been introduced.

As shown in FIGS. 5A to 5C, dissolving column 25 has a structure in which a columnar high-pressure container is filled with a filler inert to the supercritical fluid such as glass beads 26, and a minute gap between glass beads 26 is filled with solid FFRM 21. The outside of dissolving column 25 is covered with heating jacket 27 so that the internal temperature of dissolving column 25 can be controlled (see FIG. 4). Thereby, the inside of dissolving column 25 of this embodiment can be also held at a temperature equal to or higher than a critical temperature of the supercritical fluid and a pressure equal to or higher than a critical pressure of the supercritical fluid as in the high-pressure dissolving chamber of the first embodiment.

The contact area between the solid FFRM and the supercritical fluid is increased in dissolving column 25 of this embodiment by such a constitution. Thereby, even if the mechanical stirring mechanism as shown in FIG. 2 is not provided, the solid FFRM is rapidly dissolved in the supercritical fluid. That is, by utilizing the principle of column chromatography, solid FFRM 21 is sequentially dissolved in the supercritical fluid from the upstream side of dissolving column 25, and a saturated solution of the solid FFRM is discharged from the downstream side of column 25. Thereby, in this embodiment, the solid FFRM can be more efficiently dissolved in the supercritical fluid.

Other constitutions other than a supercritical fluid adjusting part of this embodiment are the same as those of the first embodiment. A vaporizing and feed method using the vaporizing and feed apparatus of this embodiment is also the same as that of the first embodiment.

### Third Embodiment

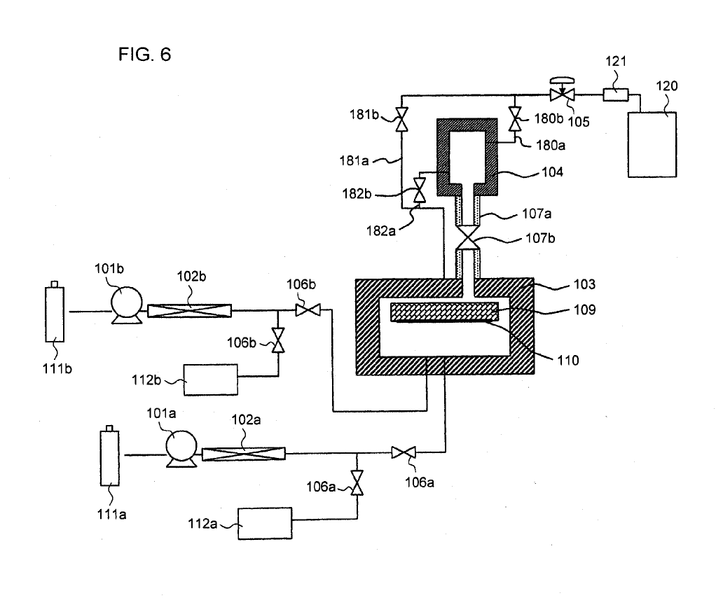

Next, a film-forming apparatus according to a third embodiment of the present invention will be described. The constitution of the film-forming apparatus according to this embodiment is shown in FIG. 6. The film-forming apparatus shown in FIG. 6 is provided with film-forming chamber 103, pressure release chamber 104, pipe 107a (a first pipe) connecting film-forming chamber 103 to pressure release chamber 104, and valve 107b (a first valve) provided on pipe 107a.

Film-forming chamber 103 and pressure release chamber 104 are stainless-steel high-pressure containers capable of withstanding a pressure equal to or higher than 20 MPa. Pipe 107a connecting film-forming chamber 103 to pressure release chamber 104 is a stainless steel pipe having a large diameter (1 inch or more). Valve 107b provided in the route of pipe 107a can respond to a control signal from a control device (a computer or the like) which are not shown, and can be instantaneously opened and closed.

Stage 109 having a built-in heater is provided in film-forming chamber 103. Semiconductor substrate 110 to be film-formed is fixed to stage 109. Semiconductor substrate 110 is fixed to stage 109 so that a surface on which a film is formed (i.e. a surface to be treated) is turned downward.

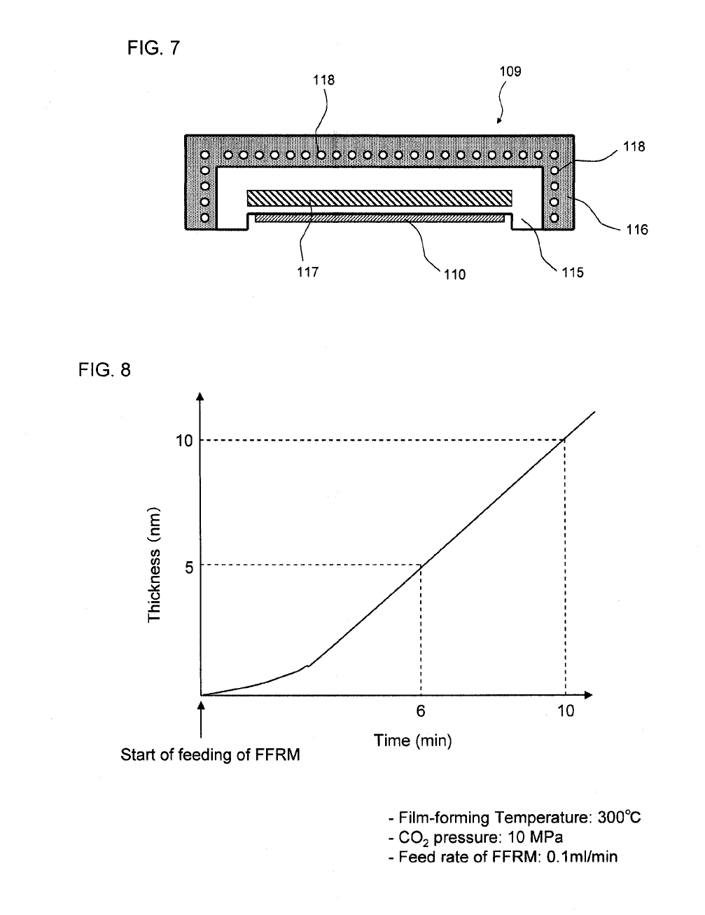

An example of the specific constitution of stage 109 is shown in FIG. 7. Stage 109 includes substrate holding part 115 and heat insulating member 116. Substrate holding part 115 is made of metal, and has a built-in heating device such as heater 117. Heater 117 is, for example, an electrically-heated wire, and heats substrate holding part 115. A temperature detecting device (for example, a thermocouple wiring) which is not shown is provided in substrate holding part 115. Semiconductor substrate 110 is maintained at a prescribed temperature by controlling electric power supplied to heater 117 based on the detection result of the temperature detecting device.

Cooling tube 118 is provided in heat insulating member 116 so as to surround the upper surface and the side surface of substrate holding part 115. The circulation of a cooling medium such as water in cooling tube 118 suppresses the propagation of heat of heater 117 to film-forming chamber 103.

Cooling tube 118 is used in order to suppress the propagation of the heat of stage 109 to the outside. In other words, cooling tube 118 is not used in order to rapidly cool semiconductor substrate 110 during the shutdown of a film-forming reaction. The stage is also enlarged accompanying recent size enlargement of the semiconductor substrate. As a result, the heat capacity of substrate holding part 115 is also increased. It is difficult to rapidly cool the semiconductor substrate using cooling tube 118.

As a method for fixing semiconductor substrate 110 to substrate holding part 115, a method for closely fixing semiconductor substrate 110 to the surface of substrate holding part 115 using static electricity may be used as well as a method using a mechanical fixing device having a hook or the like.

Returning to FIG. 6, two systems of raw material feed lines are provided in the film-forming apparatus according to this embodiment. One raw material feed line includes medium feeding equipment 111a, liquid feed pump 101a, heat exchanger 102a, FFRM feeder 112a, and valve 106a. Medium feeding equipment 111a feeds a medium (liquid) generating a supercritical fluid. The liquid fed from medium feeding equipment 111a is sent to heat exchanger 102a by liquid feed pump 101b. The fluid is heated by heat exchanger 102a to become a supercritical fluid. A first FFRM fed from FFRM feeder 112a is mixed with (dissolved in) the supercritical fluid thus produced. The supercritical fluid having the mixed first FFRM is fed to film-forming chamber 103.

The constitution of one raw material feed line is the same as that of the other feed line. That is, the raw material feed line includes medium feeding equipment 111b, liquid feed pump 101b, heat exchanger 102b, FFRM feeder 112b, and valve 106b. A medium (liquid) fed from medium feeding equipment 111b is heated by heat exchanger 102b to become a supercritical fluid. A second FFRM fed from the FFRM feeder 112b is mixed with (dissolved in) the supercritical fluid. The supercritical fluid having the mixed second FFRM is fed to film-forming chamber 103.

When a film is formed using three kinds or more of FFRMs, three systems or more of raw material feed lines which are the same as those described above may be provided. All of the plurality of raw material feed lines may not have the same structure. The structure of the feed line may be appropriately changed according to the characteristics of the raw material to be fed.

Film-forming chamber 103 and pressure release chamber 104 are connected to back pressure adjuster 105 through a plurality of pipes. A valve is provided on each of the pipes. Back pressure adjuster 105 is connected to recovery tank 120 through heat exchanger 121. Recovery tank 120 is used in order to recover a FFRM remaining after carrying out the film formation and a by-product produced in the film-forming reaction. Specifically, pressure release chamber 104 is connected to back pressure adjuster 105 through pipe 180a (a second pipe) on which valve 180b (a second valve) is provided. Film-forming chamber 103 is connected to back pressure adjuster 105 through pipe 181a (a third pipe) on which valve 181b (a third valve) is provided. Furthermore, film-forming chamber 103 and pressure release chamber 104 are connected to each other through pipe 182a (a fourth pipe) on which valve 182b (a fourth valve) is provided.

A stainless steel pipe is used for the pipe provided on each of the raw material feed lines. A stainless steel pipe is used also for each of pipes 180a, 181a, 182a. However, the pipe of each of the raw material feed lines, and pipes 180a, 181a and 182a have a diameter smaller than that of pipe 107a.

Next, a film-forming method according to the third embodiment of the present invention will be described. In this embodiment, the case in which carbon dioxide (CO₂) is used as the supercritical fluid and an oxide silicon film (SiO₂) is formed on semiconductor substrate 110 will be specifically described.

The carbon dioxide is known to be in a supercritical state at a temperature equal to or higher than a critical temperature and a pressure equal to or higher than a critical pressure. Critical temperature Tc of the carbon dioxide is 31.1° C., and critical pressure Pc is 7.38 MPa.

A liquid carbon dioxide cylinder is used as medium feeding equipments 111a and 111b shown in FIG. 6. The gaseous carbon dioxide may be cooled to 0° C. by a cooler, to thereby feed the carbon dioxide changed to a liquid state.

A vaporized TEOS (tetraethoxysilane) gas and an oxygen gas (O₂) can be used as the FFRM.

Semiconductor substrate 110 is fixed on stage 109 in film-forming chamber 103. At this time, semiconductor substrate 110 is fixed so that the surface to be treated of semiconductor substrate 110 is turned downward. Valve 107b between film-forming chamber 103 and pressure release chamber 104 is closed.

Next, the supercritical carbon dioxide is fed into film-forming chamber 103 set to a prescribed pressure (10 MPa in this embodiment). The temperature of the carbon dioxide at this time is set to a temperature (100° C. in this embodiment) equal to or higher than the critical temperature and sufficiently lower than a film-forming reaction temperature. The supercritical state of the carbon dioxide is maintained in film-forming chamber 103. At this point, the FFRM is not fed.

Continuously, semiconductor substrate 110 is heated by heater 117 (FIG. 7), to raise the temperature of semiconductor substrate 110 to a prescribed temperature (300° C. in this embodiment) at which the film-forming reaction occurs.

After conditions required for the film-forming reaction are achieved, the FFRMs (TEOS and oxygen) are respectively mixed with the supercritical carbon dioxide from FFRM feeders 112a and 112b. Thereby, the supercritical carbon dioxide with which the FFRM is mixed is fed into film-forming chamber 103.

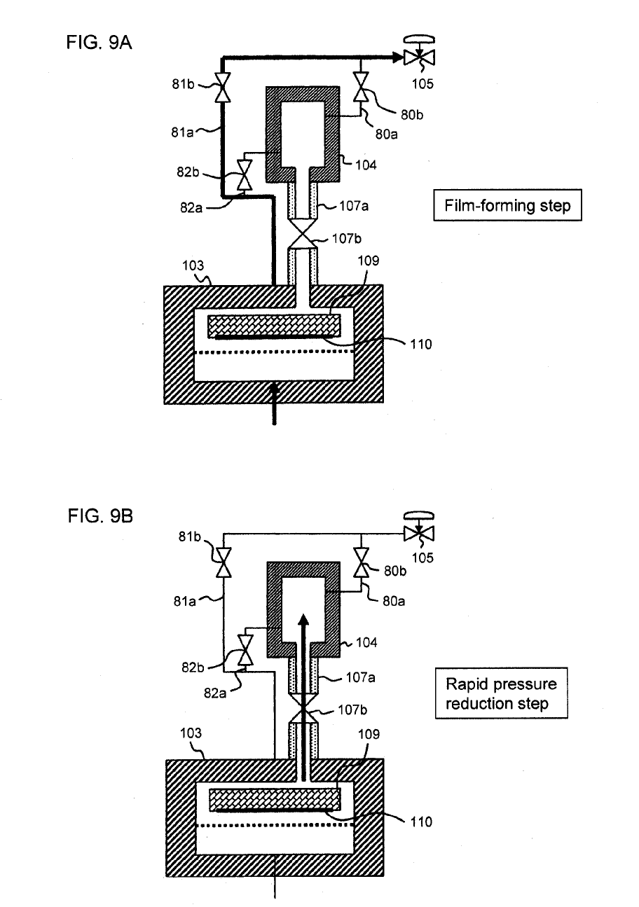

The thermal decomposition of the fed TEOS and the reaction between the TEOS and oxygen occur on the surface of heated semiconductor substrate 110, and thereby the oxide silicon film is deposited on the surface of semiconductor substrate 110. An example of the relationship between film-forming time and film thickness when the oxide silicon film is formed is shown in FIG. 8. In this embodiment, the oxide silicon film having a film thickness of about 5 nm can be deposited by continuously feeding the FFRM for 6 minutes. Since the relationship between the film-forming time and the film thickness is changed by a film-forming temperature or the feed rate of the FFRM, the above-mentioned relationship is previously investigated according to the film-forming conditions to be used.

When the oxide silicon film reaches a prescribed film thickness, the shutdown of heating caused by heater 117, the shutdown of feeding of the FFRM, and the rapid pressure reduction of the supercritical carbon dioxide are simultaneously performed, to shut down the film-forming reaction. The rapid pressure reduction is performed by opening valve 107b shown in FIG. 6.

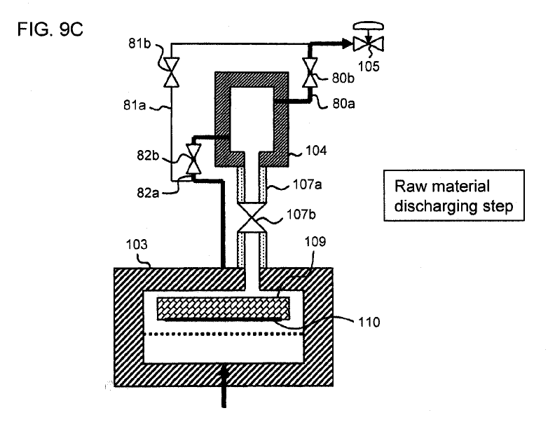

The flow of the supercritical fluid (CO₂) in each of steps of the film-forming method according to the third embodiment of the present invention is shown in FIGS. 9A to 9C. FIG. 9A shows the flow of the supercritical fluid during a film-forming step. FIG. 9B shows the flow of the supercritical fluid during a rapid pressure reduction step. FIG. 9C shows the flow of the supercritical fluid during a raw material discharging step. The thick line in each of FIGS. 9A to 9C shows the passage route of the supercritical fluid.

During conducting the film-forming reaction, the supercritical fluid flows to back pressure adjuster 105 from a discharge port (not shown) provided in the upper part of film-forming chamber 103 (FIG. 9A). The supercritical fluid passing through back pressure adjuster 105 is collected to recovery tank 120 shown in FIG. 6. Valve 8 provided on the route in which the supercritical fluid does not flow is closed.

During the rapid pressure reduction, the discharge port provided in the upper part of film-forming chamber 103 is closed, and valve 107b is opened. Thereby, the supercritical fluid is discharged at once to pressure release chamber 104 through a pipe having a large diameter (FIG. 9B). Herein, pressure in pressure release chamber 104 is previously maintained in the range of from the atmospheric pressure (about 0.1 MPa) to about 4 MPa. Then, if valve 107b between film-forming chamber 103 and pressure release chamber 104 is opened, pressure in film-forming chamber 103 is rapidly reduced to the critical pressure (7.38 MPa when the supercritical fluid is the carbon dioxide) or lower of the supercritical fluid. In this embodiment, the pressure in pressure release chamber 104 before opening valve 107b is set to atmospheric pressure. The specific calculated value of pressure change is shown in FIG. 9.

When a calculation is made, the volume of film-forming chamber 103 is set to 10 L (liter), and the volume of pressure release chamber 104 is set to 7 L. Pressure release chamber 104 is held at the atmospheric pressure (0.1 MPa) before opening valve 107b. For simplification, the calculation is made without taking into consideration temperature decrease caused by adiabatic expansion of the carbon dioxide, and temperature increase caused by heater heating in the proximity of the semiconductor substrate. (Even rigorous calculation including the temperature decrease and the temperature increase has a limited influence on pressure).

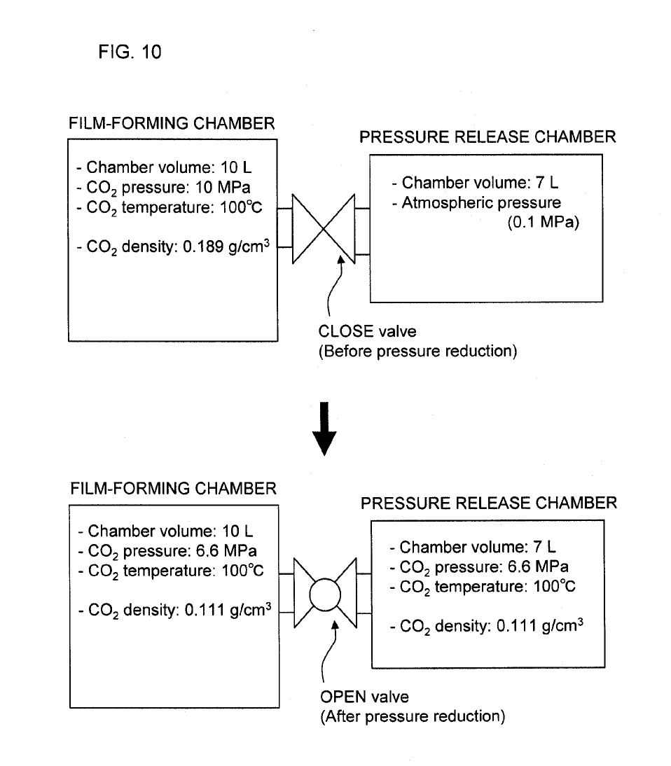

As shown in FIG. 10, the pressure in film-forming chamber 103 is rapidly decreased to 6.6 MPa by opening valve 107b and connecting pressure release chamber 104 to film-forming chamber 103. The carbon dioxide set to the critical pressure (7.38 MPa) or lower is changed to gaseous carbon dioxide by connecting pressure release chamber 104 to film-forming chamber 103.

The solubility of the FFRM in the medium (the carbon dioxide in this embodiment) which is not in a supercritical state is markedly reduced. As a result, the FFRM (the TEOS in this embodiment) is rapidly deposited. The deposited FFRM settles on the bottom of film-forming chamber 103. Thereby, the concentration of the FFRM in film-forming chamber 103 is rapidly reduced, and the film-forming reaction is momentarily shut down.

Semiconductor substrate 110 is disposed on the upper part of film-forming chamber 103. Therefore, adhesion of the deposited FFRM to semiconductor substrate 110 is avoided. Since semiconductor substrate 110 particularly is held with a surface to be treated thereof turned downward, adhesion of the deposited FFRM to the surface to be treated of semiconductor substrate 110 is avoided.

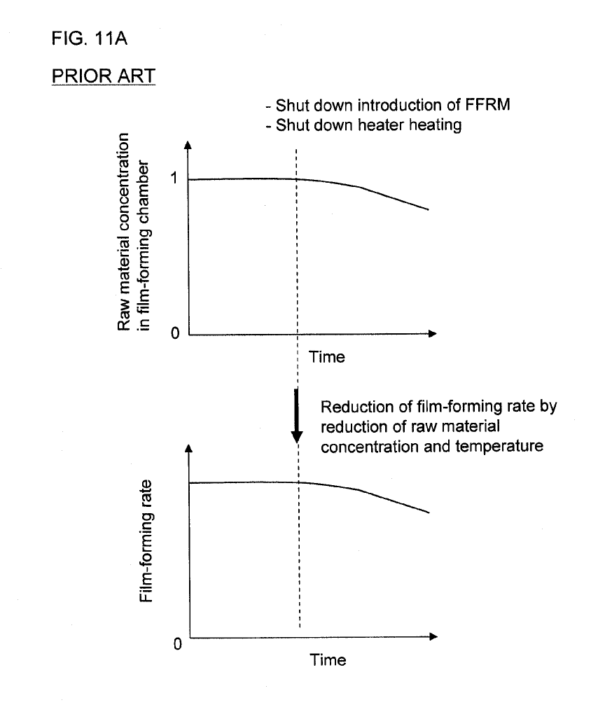

Change in a raw material concentration and a film-forming rate in a film-forming chamber in a conventional film-forming method is schematically shown in FIG. 11A. On the other hand, change in a raw material concentration and a film-forming rate in a film-forming chamber in the film-forming method of the present invention is schematically shown in FIG. 11B.

As shown in FIG. 11A, even if raw material feeding is shut down in the conventional method, the raw material concentration in the film-forming chamber is not rapidly reduced, but slowly reduced. Even if heating by the heater is shut down, the surface temperature of the semiconductor substrate is not rapidly reduced. Thereby, even if the feeding of the FFRM and the heating by the heater are simultaneously shut down, the film-forming rate does not become zero, and the film-forming reaction continuously proceeds (an overshoot state).

On the other hand, as shown in FIG. 10B, in the film-forming method of the present invention, the concentration of the FFRM in the proximity of the surface of the semiconductor substrate can be rapidly made close to zero by utilizing the deposition of the FFRM. Thereby, the film-forming reaction can be momentarily shut down without generating an overshoot of film formation.

When the film-forming reaction is shut down and the temperature of semiconductor substrate 110 is lower than the film-forming reaction temperature, the supercritical carbon dioxide is refed into film-forming chamber 103 and pressure release chamber 104 through the route shown in FIG. 9C. Thereby, the insides of film-forming chamber 103 and pressure release chamber 104 are increased to a prescribed pressure (10 MPa in this embodiment) equal to or higher than the critical pressure. The temperature of the supercritical carbon dioxide fed at this time is set to 100° C. as in that before starting the film formation. The temperature is sufficiently lower than the film-forming reaction temperature. At this time, heater 117 (FIG. 7) is shut down. Therefore, even if the inside of film-forming chamber 103 returns to the supercritical state, and the FFRM that was deposited and that settled is dissolved in the supercritical fluid again, the film-forming reaction is not resumed on the surface of the semiconductor substrate.

The dissolved FFRM passes through the route shown in FIG. 9C, and is discharged to recovery tank 120 shown in FIG. 6. After the discharging step of the FFRM is completed, the film-forming chamber 103 is reduced to atmospheric pressure, and semiconductor substrate 110 is removed. As described above, the film-forming step is completed.

When film thickness is controlled by utilizing rapid pressure reduction, the pressure release chamber which is the feature of the film-forming apparatus of the present invention has the following two functions:

(1) To control a pressure after rapid pressure reduction; and
(2) To avoid breakage of the apparatus accompanying rapid pressure reduction.

The pressure control of the item (1) will be specifically described. The back pressure adjuster is used for pressure reduction in the film-forming chamber in a conventional film-forming apparatus. However, since it is necessary to control the discharge and the discharge shutdown of the supercritical fluid using the valve in the film-forming apparatus using the supercritical fluid, the flow passage in the back pressure adjuster is narrow, which complicates realization of rapid pressure drop. This is because the pressure is adjusted by continuously discharging the supercritical fluid at a comparatively slow flow rate for a fixed period in the back pressure adjuster for the supercritical fluid.

On the other hand, in the present invention in which the pressure release chamber is used for pressure reduction in the film-forming chamber, the pressure after pressure reduction is automatically determined according to the volume difference between the film-forming chamber and the pressure release chamber, and the internal pressure difference before releasing pressure between the film-forming chamber and the pressure release chamber. Therefore, rapid pressure reduction can be achieved merely by placing the valve between both chambers in a fully opened state. Thereby, in the present invention, the film-forming reaction can be instantaneously shut down.

Breakage of the apparatus of the item (2) will be specifically described. When the rapid pressure reduction is carried out, one concern is freezing of the pipe and related parts (a valve and a seal ring or the like in the back pressure adjuster) caused by adiabatic cooling accompanying rapid pressure reduction (i.e. by cooling accompanying the adiabatic expansion of the carbon dioxide). Specifically, the following description is supposed. The carbon dioxide flowing through the pipe is in a dry ice state, and the pipe is clogged with the carbon dioxide. Alternatively, breakage of a plastics component, such as the seal ring, is caused by freezing.

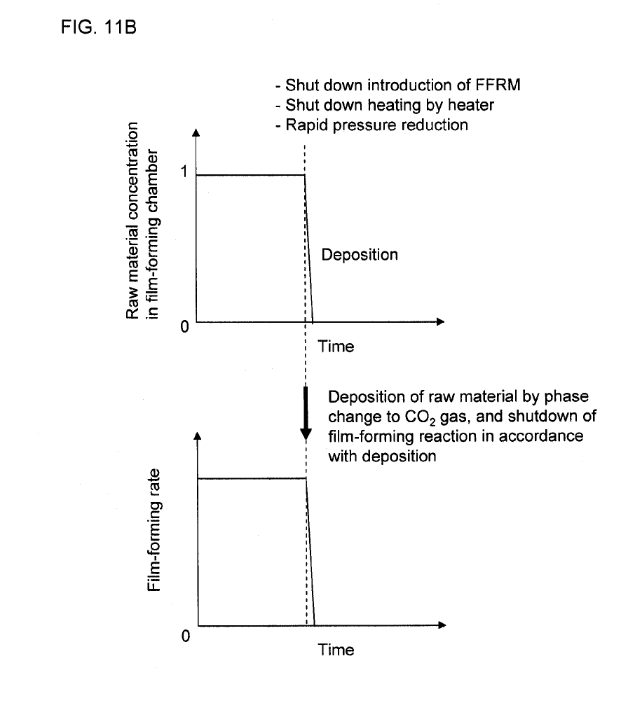

Herein, as shown in FIG. 12A, when the carbon dioxide (for example, pressure: 10 MPa) in the film-forming chamber is roundly discharged to the outside (recovery tank) without change through the back pressure adjuster, the pressure of the carbon dioxide is decreased to the atmospheric pressure (about 0.1 MPa) at once immediately after passing through the back pressure adjuster. Thereby, adiabatic cooling occurs in the proximity of the back pressure adjuster, to generate freezing. Furthermore, the freezing region is gradually expanded during discharge of the carbon dioxide. Finally, the pipe and the related part are completely frozen.

On the other hand, as shown in FIG. 11B, even if the pressure of the pressure release chamber before releasing the valve is in an atmospheric pressure state, when the pressure is reduced through the pressure release chamber, the pressure of the carbon dioxide in the film-forming chamber after releasing the valve is not reduced to the atmospheric pressure. That is, as shown in FIG. 10, the pressure in the film-forming chamber after releasing the valve is reduced up to, for example, about 6.6 MPa. Thereby, adiabatic cooling is suppressed. Since pressure reduction is momentarily finished, adiabatic cooling does not continue for a long time. Thereby, a related part such as a pipe or a valve is not frozen. Furthermore, since it is not necessary to rapidly reduce the pressure when the carbon dioxide in the pressure release chamber is discharged to the atmospheric pressure recovery tank, adiabatic cooling can be avoided by gradually reducing the pressure.

The film-forming chamber, the pressure release chamber and the pipe or the like have a thickness that can withstands a sufficient high pressure and is made of stainless steel. Thereby, physical breakage caused by pressure change can also be avoided.

Thus, the rapid pressure reduction can be easily and safely carried out by the structure in which the film-forming chamber and the pressure release chamber are connected through the valve.

As described above, according to the present invention, a film-forming reaction can be rapidly shut down. As a result, the overshoot of the film formation is avoided, to easily control film thickness during film formation, and thereby an accurate film can be formed.

The kind of the supercritical fluid used for the film-forming apparatus and the film-forming method of the present invention is not particularly limited, and can be appropriately selected according to the characteristics of the FFRM. For example, supercritical water (critical temperature Tc=374° C., critical pressure Pc=22 MPa) can be also used.

The film-forming method of the present invention can be also applied to formation of thin films as well as to the formation of oxide silicon film. For example, a metal chelate compound is used as one FFRM, and oxygen, ozone, hydrogen, nitrogen, ammonia and steam or the like that react with the metal chelate compound to produce a film can be used as other FFRM. Thereby, the film containing metal, for example, a titanium oxide film (TiO₂) can be formed.

Examples of the metal chelate compound used as the FFRM include bis(ethylcyclopentadienyl)ruthenium, tris(2,4-octadionato)ruthenium, pentakis(dimethylamino)tantalum, pentaethoxy tantalum, tetra-t-butoxytitanium, tetrakis(N-ethyl-N-methylamino)titanium, iridium acetylacetone, and platinum acetylacetone.

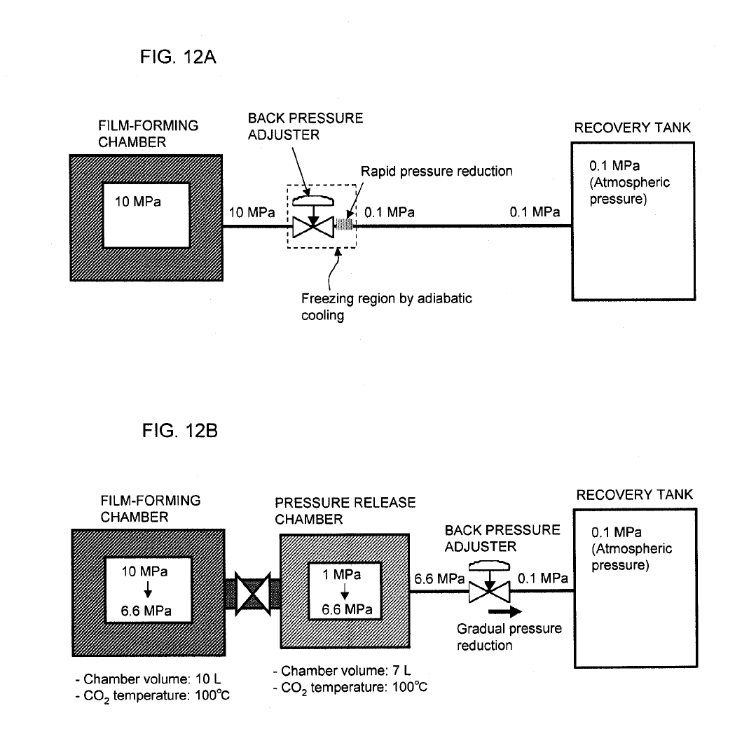

Film-forming chamber 103 shown in FIG. 6 or the like can also be changed as shown in FIG. 13. Two windows (incident window 130a, detection window 130b) are provided in the lower part of film-forming chamber 103 shown in FIG. 13. Therefore, light can be made incident into film-forming chamber 103 through incident window 130a, and light reflected on semiconductor substrate 110 can be emitted from detection window 130b. That is, the light reflected on semiconductor substrate 110 can be externally monitored. Therefore, measuring apparatuses 131 capable of measuring the thickness of a film formed on a semiconductor substrate using light, such as an ellipsometry are disposed as shown in FIG. 13, and thereby the thickness of the film formed on the semiconductor substrate can be measured. Therefore, it is also possible to assess timing for performing an operation for shutting down the film-forming reaction while monitoring the actual film thickness during the film-forming process.

Incident window 130a and detection window 131b have a thickness capable of sufficiently withstanding a pressure in a supercritical state, and are made of sapphire.

### Fourth Embodiment

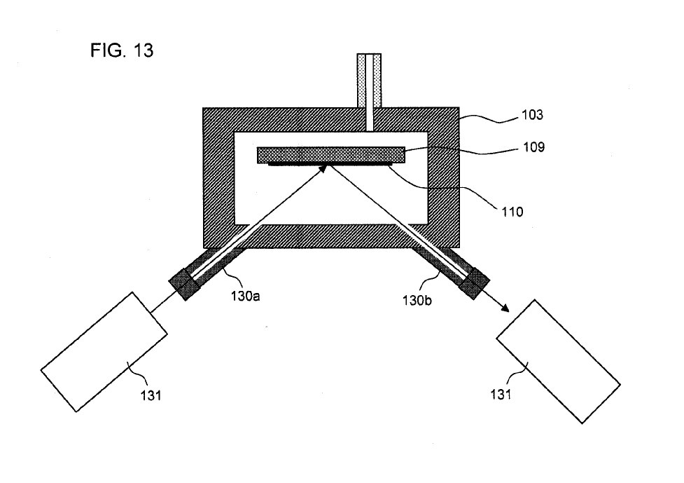

FIG. 14 is a plan view showing the schematic constitution of a film-forming apparatus according to a fourth embodiment of the present invention.

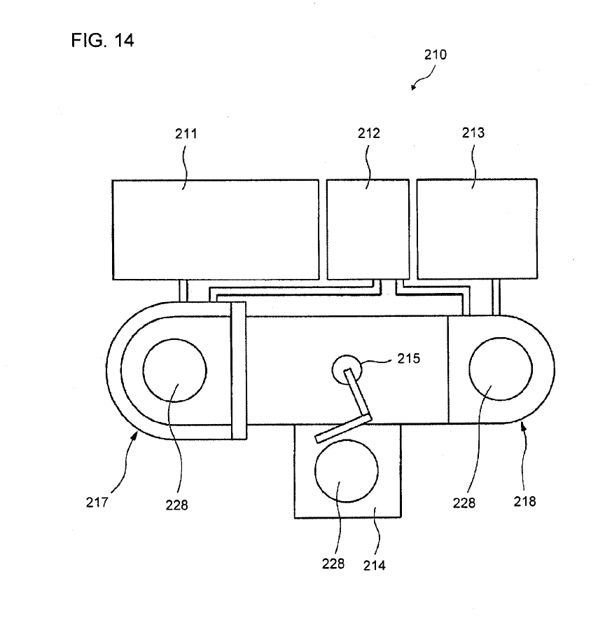

With reference to FIG. 14, film-forming apparatus 210 of this embodiment has FFRM liquid adjuster 211, removing device 212, reaction reagent feeder 213, substrate charging mechanism 214, substrate transferring device 215, FFRM deposition chamber 217 as a first chamber, heater 226 for heating a substrate (not shown in FIG. 14, but see FIG. 15) as a heating device, shower plate 231 (not shown in FIG. 14, but see FIG. 15), and reaction chamber 218 as a second chamber.

FFRM liquid adjuster 211 dissolves a FFRM in a solvent (liquid), and adjusts the concentration. FFRM liquid adjuster 211 is connected to FFRM deposition chamber 217, and feeds a FFRM liquid which is a solvent that has the FFRM dissolved at a prescribed concentration, to FFRM deposition chamber 217.

Removing device 212 is connected to FFRM deposition chamber 217 and reaction chamber 218. Removing device 212 discharges an excessive solvent and an excessive reaction reagent or the like discharged from FFRM deposition chamber 217 and reaction chamber 218, to the outside of film-forming apparatus 210.

Reaction reagent feeder 213 is connected to reaction chamber 218. Reaction reagent feeder 213 feeds a reaction reagent to reaction chamber 218. For example, various catalysts, initiators for polymerization and various gases (for example, hydrogen and oxygen) or the like can be used as the reaction reagent.

Substrate charging mechanism 214 is a member on which a closed type container, such as Front Opening Unified Pod (FOUP), including a plurality of semiconductor substrates (substrates to be treated) is placed.

Substrate transferring device 215 is a robot arm for transferring semiconductor substrate 228 stored in the FOUP into FFRM deposition chamber 217, transferring semiconductor substrate 228 in FFRM deposition chamber 217 to reaction chamber 218, or recovering semiconductor substrate 228 placed in reaction chamber 218 into the FOUP.

FIG. 15 is a sectional view showing the constitution of the inside of the FFRM deposition chamber shown in FIG. 14. In FIG. 15, the same constituent portions as those of film-forming apparatus 210 shown in FIG. 14 are provided with the same reference numeral.

With reference to FIG. 15, FFRM deposition chamber 217 has FFRM liquid feed hole 222 and exhaust hole 223.

FFRM liquid feed hole 222 is formed so as to pass through a portion of FFRM deposition chamber 217 constituting bottom face 217a exposed to space 221 formed in FFRM deposition chamber 217. FFRM liquid feed hole 222 is a hole for feeding the FFRM liquid to space 221 formed in FFRM deposition chamber 217.

Exhaust hole 223 is formed so as to pass through the side wall of FFRM deposition chamber 217. Exhaust hole 223 is a hole for discharging a solvent introduced into FFRM deposition chamber 217, to the outside of FFRM deposition chamber 217. FFRM deposition chamber 217 has a thickness capable of withstanding a high-pressure state of an atmospheric pressure or more, and is made of stainless steel or the like.

FFRM deposition chamber 217 constituted as described above is a chamber which accommodates semiconductor substrate 228, to which a liquefied FFRM liquid produced by dissolving the FFRM in the solvent is fed, and in which the FFRM dissolved in the solvent is deposited on surface 228a (film-forming surface) of semiconductor substrate 228 by phase-transitioning the solvent contained in the FFRM liquid to a gas from a liquid. Surface 228a (film-forming surface) of semiconductor substrate 228 is placed so that surface 228a is turned downward in FFRM deposition chamber 217.

With reference to FIG. 15, heater 226 for heating a substrate has a function of a stage for fixing semiconductor substrate 228, and is provided on ceiling portion 217b of FFRM deposition chamber 217 exposed to space 221.

Heater 226 for heating a substrate has substrate disposing surface 226a brought in contact with back face 228b of semiconductor substrate 228. Surface 228a (film-forming surface) of semiconductor substrate 228 fixed to substrate disposing surface 226a is disposed so as to face FFRM liquid feed hole 222. Heater 226 for heating a substrate heats semiconductor substrate 228 fixed to substrate disposing surface 226a to a prescribed temperature.

Heater 226 for heating a substrate has a heat insulator or a circulating tube for a cooling medium or the like disposed on a side surface and an upper surface other than substrate disposing surface 226a, to prevent heat from being conducted to the inner wall of FFRM deposition chamber 217.

Shower plate 231 is disposed between bottom face 217a of FFRM deposition chamber 217 and surface 228a of semiconductor substrate 228 so as to face surface 228a of semiconductor substrate 228.

FFRM liquid is fed to surface 228a of semiconductor substrate 228 through shower plate 231.

Reaction chamber 218 is connected to removing device 212 and reaction reagent feeder 213. Reaction chamber 218 is a chamber which is different from FFRM deposition chamber 217. In reaction chamber 218, a reaction is caused in the FFRM (the FFRM formed in FFRM deposition chamber 217), formed on surface 228a of semiconductor substrate 228, by heating, or adding the reaction reagent, and thereby a film is formed on surface 228a of semiconductor substrate 228.

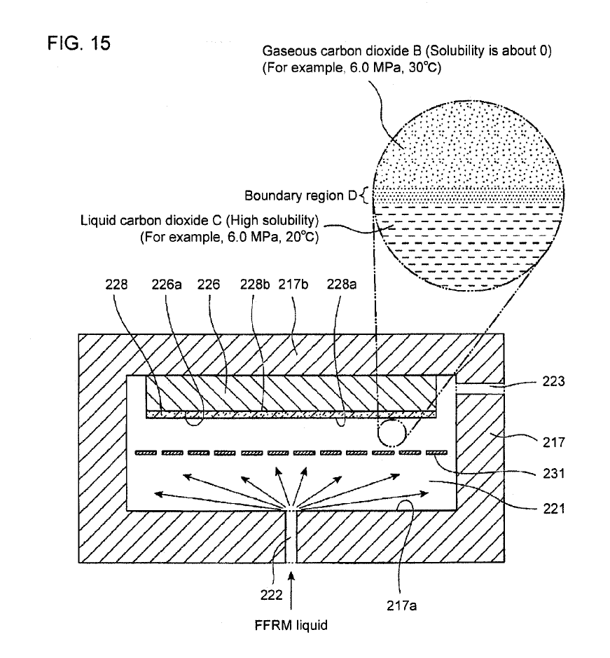

Herein, with reference to FIGS. 16A, 16B and 16C, a film-forming method according to a fourth embodiment of the present invention that is performed using film-forming apparatus 210 provided with FFRM deposition chamber 217, heater 226 for heating a substrate and shower plate 231, will be described. FFRM deposition chamber 217, heater 226 for heating a substrate and shower plate 231 are shown in FIG. 15.

FIGS. 16A, 16B and 16C describe the film-forming method of this embodiment, and illustrate semiconductor substrate 228 in a state in which semiconductor substrate 228 shown in FIG. 15 is turned upside down.

First, in a step shown in FIG. 16A, there is prepared FFRM liquid 233 having FFRM 235 dissolved at a prescribed concentration in solvent 234 (liquid) so that film 239 (see FIG. 16C) formed in a reaction step has a desired thickness. Then, FFRM liquid 233 is brought into contact with surface 228a of semiconductor substrate 228.

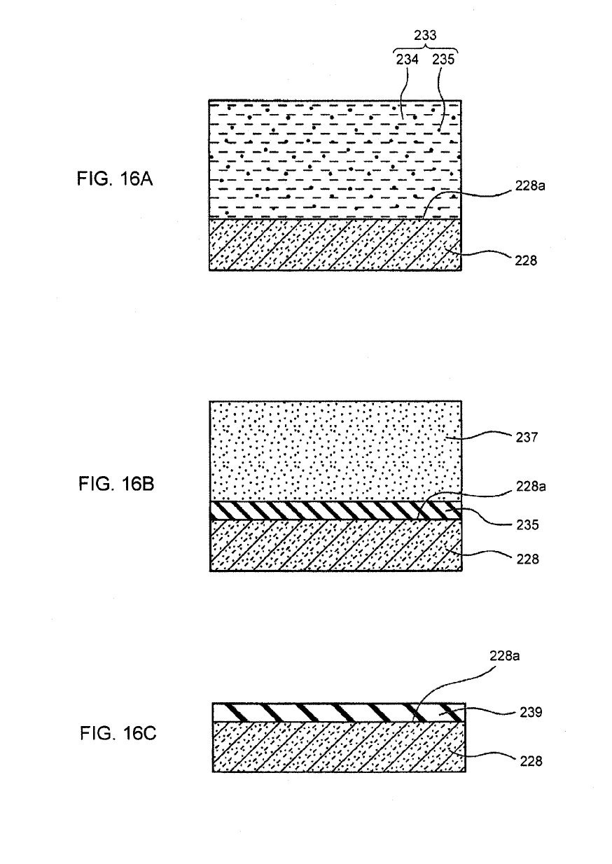

Carbon dioxide (CO₂) can be used as solvent 234 (liquid) that dissolves FFRM 235. The carbon dioxide is known to be liquidized at a temperature and a pressure equal to or higher than a triple point (−56.6° C., 0.52 MPa) (see FIG. 17 described later).

For example, a styrene monomer can be exemplified as FFRM 235. When solvent 234 is liquefied carbon dioxide, the concentration of FFRM 235 contained in FFRM liquid 233 is preferably set to 5 to 50% in molar fraction.

The specific concentration of FFRM 235 in the solvent may be set so that the concentration is most suitable according to a film-forming rate or a film thickness to be deposited. By dissolving FFRM 235 at a high concentration in solvent 234, in a step shown in FIG. 16B described later, FFRM 235 can be quickly deposited on surface 228a of semiconductor substrate 228 to a desired thickness.

Herein, with reference to FIG. 17, the carbon dioxide that acts as solvent 234 will be described. FIG. 17 schematically shows a pressure-temperature phase diagram for carbon dioxide.

With reference to FIG. 17, liquid carbon dioxide shown by a black dot A in FIG. 17 is phase changed to a gas state from a liquid state in accordance with a temperature change or pressure change. In accordance with a phase change, the density of the carbon dioxide is rapidly changed.

The solubility of FFRM 235 in the medium (also containing solvent 234) correlates with the density of the medium. Thereby, rapid density change causes a rapid solubility change, to make it possible to deposit FFRM 235 that is dissolved in the medium at once (and instantaneously).

Herein, since solvent 234 before being phase changed usually has high solubility, the molar fraction of FFRM 235 in solvent 234 is far higher than that in the case in which a gas is used as the medium.

Therefore, a large amount of FFRM 235 can be deposited as a precipitate on surface 228a of semiconductor substrate 228.

Such a large amount of FFRM 235 cannot be deposited on surface 228a of semiconductor substrate 228 at once in raw material feeding using a gaseous or supercritical medium. The FFRM 235 can be deposited only by phase-changing the medium to the gas state having the lowest solubility from the liquid state having the highest solubility.

In the present invention, the phase change in the medium to the gas state from the liquid state is utilized, and thereby FFRM 235 adheres to surface 228a of semiconductor substrate 228. In the following description, the case in which liquefied carbon dioxide is used as solvent 234 and in which phase change is caused by heating will be described as an example.

Then, in a step shown in FIG. 16B, FFRM liquid 233 having FFRM 235 dissolved at a prescribed concentration in the liquid carbon dioxide is phase changed by heating FFRM liquid 233 by heater 226 for heating a substrate. FFRM 235 is deposited on surface 228a of semiconductor substrate 228 to a desired thickness by depositing FFRM 235 that is at once dissolved in FFRM liquid 233.

Thereby, FFRM liquid 233 is separated into FFRM 235 deposited on surface 228a of semiconductor substrate 228 and carbon dioxide which is gas 237 brought into contact with FFRM 235.

In the present invention, semiconductor substrate 228 is located close to the ceiling portion of FFRM deposition chamber 217 so that the film-forming surface (surface 228a) is turned downward. The constitution can keep the carbon dioxide heated to be in the gas state, in only the proximity of the film-forming surface of the semiconductor substrate. Thereby, adhesion of the deposited FFRM to the inner wall of the FFRM deposition chamber can be suppressed, and the FFRM can be selectively deposited on the semiconductor substrate.

The description “FFRM 235 is deposited” in this and subsequent embodiments means not the final deposition of the film in accordance with the heat reaction or the like of the FFRM carried out in the conventional common film-forming apparatus (for example, CVD apparatus) or the like but adhesion of the FFRM 235 in the state before the reaction.

Therefore, when semiconductor substrate 228 for the next operation is placed in FFRM deposition chamber 217, and the solvent containing FFRM 235 is fed, FFRM 235 that adheres slightly to the inner wall of FFRM deposition chamber 217 by deposition is also redissolved, and is recovered. That is, the inner wall of FFRM deposition chamber 217 is simultaneously cleaned.

Then, in a step (reaction step) shown in FIG. 16C, after FFRM 235 is deposited on surface 228a of semiconductor substrate 228, semiconductor substrate 228 on which FFRM 235 is deposited is removed from FFRM deposition chamber 217. Then, semiconductor substrate 228 removed is moved into reaction chamber 218.

Film 239 is formed on surface 228a of semiconductor substrate 228 by reacting deposited FFRM 235 on surface 228a of semiconductor substrate 228 by adding the reaction reagent or by heating. The treatment for the above-mentioned step shown in FIG. 16C can be performed with reaction chamber 218 being in an atmospheric pressure state or under a reduced pressure.

The film-forming method according to this embodiment is characterized in that film-forming apparatus 210 shown in FIG. 14 is used, and a film-forming reaction is performed in two independent steps, a raw material depositing step (the step shown in FIG. 16B) and a reaction step (the step shown in FIG. 16C).

In the film-forming method using the film-forming apparatus of this embodiment, FFRM 235 is deposited only on surface 228a of semiconductor substrate 228 in FFRM deposition chamber 217, and FFRM 235 that is deposited on surface 228a of semiconductor substrate 228 is then reacted only on semiconductor substrate 228 in reaction chamber 218. Thereby, the generation of particles in FFRM deposition chamber 217 and reaction chamber 218 can be suppressed without complicating the constitution of film-forming apparatus 210 (in other words, without increasing the cost of film-forming apparatus 210), and film 239 having good morphology can be formed.

Since semiconductor substrate 228 having the state in which FFRM is already deposited is moved and is placed in reaction chamber 218 in which film 239 is formed, the generation of the adhesion (residue) of FFRM 235 or film 239 itself can be avoided. Therefore, the inside of reaction chamber 218 can always be kept clean.

The adhesion of FFRM 235 deposited on the inner wall of FFRM deposition chamber 217 to semiconductor substrate 228 can be suppressed by the structure in which semiconductor substrate 228 is placed with the film-forming surface turned downward close to the ceiling portion of FFRM deposition chamber 217. Furthermore, FFRM 235 that adheres slightly to the inner wall of FFRM deposition chamber 217 can be also redissolved in the solvent during the next operation, to be removed.

Thereby, since the frequency of cleaning performed with film-forming apparatus 210 shut down can be greatly reduced, the operation efficiency of film-forming apparatus 210 can be improved.

### Fifth Embodiment

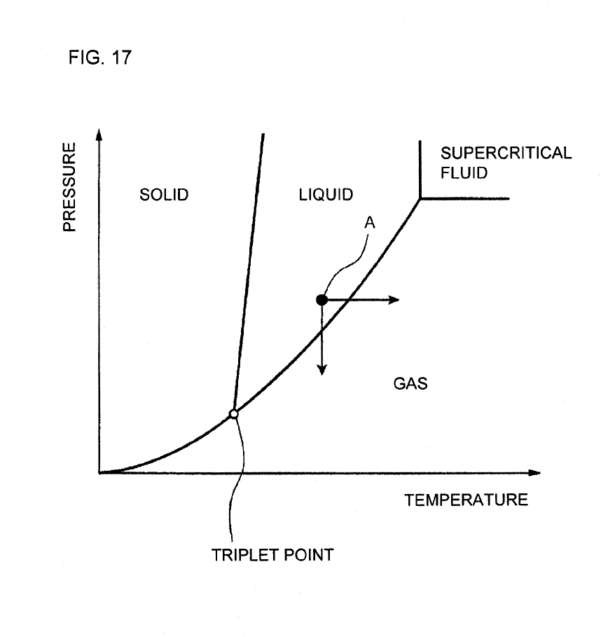

FIG. 18 is a sectional view of a FFRM deposition chamber and a heater for heating a substrate which are provided in a film-forming apparatus according to a fifth embodiment of the present invention.

The film-forming apparatus of this embodiment is constituted as in film-forming apparatus 210 of the fourth embodiment except that a structure shown in FIG. 18 (specifically, FFRM deposition chamber 41 and heater 42 for heating a substrate) is provided instead of a structure shown in FIG. 15 (specifically, single substrate type FFRM deposition chamber 217 and heater 226 for heating a substrate).

FFRM deposition chamber 41 is a batch type chamber, where a plurality of semiconductor substrates 28 are placed at prescribed intervals in the vertical direction. FFRM liquid feed hole 222 is formed in FFRM deposition chamber 41. Exhaust hole 223 is formed in the upper part of FFRM deposition chamber 41.

Heater 42 for heating a substrate is disposed around FFRM deposition chamber 41. Heater 42 for heating a substrate heats a plurality of semiconductor substrates 28 accommodated in FFRM deposition chamber 41 to a prescribed temperature through FFRM deposition chamber 41.

When a film is formed using the above-mentioned batch type FFRM deposition chamber 41, it becomes difficult to change only the temperature of the proximity of surface 228a of each of semiconductor substrates 28 and to rapidly and correctly change the temperature of whole FFRM deposition chamber 41.

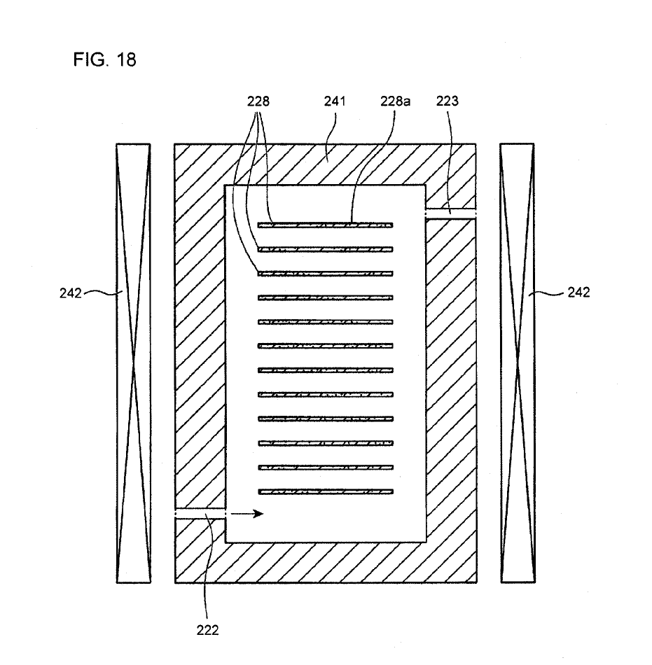

Then, the FFRM is deposited not by phase change based on temperature change, but by utilizing density change based on pressure change as shown in FIG. 19. FIG. 19 is a view showing a result obtained by measuring change in density of carbon dioxide when the pressure of the carbon dioxide is changed.

With reference to FIG. 19, the liquid carbon dioxide at a temperature of 20° C. is changed to a gas state at a pressure of about 5.8 MPa, which results in a drastic decrease in the density. Similarly, the liquid carbon dioxide at a temperature of 25° C. is changed to a gas state at a pressure of about 6.5 MPa, which results in a drastic decrease in the density.

Therefore, FFRM can be deposited on surface 228a of semiconductor substrate 228 by slightly lowering the pressure of the carbon dioxide maintained in a high-pressure state (for example, 6 MPa) at a prescribed temperature (for example, 20° C.) (reducing the pressure to, for example, 5.5 MPa) to cause phase change from a liquid to a gas.

Since the FFRM is deposited throughout FFRM deposition chamber 41 in this case, the FFRM also adheres to a portion other than surface 228a of semiconductor substrate 228. Since the FFRM adhering to the portion other than surface 228a of semiconductor substrate 228 is redissolved when the liquid carbon dioxide is introduced during the next operation, the inner wall of FFRM deposition chamber 41 can be cleaned, and the FFRM can be reutilized.

That is, the film-forming method and film-forming apparatus of this embodiment enables the cleaning of the inner wall of FFRM deposition chamber 41, the unreacted FFRM adhering to the inner wall, and the recovery of the FFRM, in order to separately react FFRM in reaction chamber 218.

After the FFRM is deposited on surface 228a of semiconductor substrate 228, semiconductor substrate 228 is transported to a batch type reaction chamber (not shown) separately provided, where a prescribed film is formed by carrying out a polymerization reaction.

### Example

Next, mainly with reference to FIGS. 14 to 16, a film-forming method will be more specifically described by giving the example of the case in which a polymer film (an example of film 239 shown in FIG. 16C) is formed on semiconductor substrate 228 using film-forming apparatus 210 described in the fourth embodiment. The polymer film is used an interlayer insulating film. In the case of a film having low dielectric constant in addition to an insulation property, the reduction effect of parasitic capacitance between wirings is obtained.

First, semiconductor substrate 228 was set to substrate charging mechanism 214 of film-forming apparatus 210 shown in FIG. 14. Semiconductor substrate 228 was then transferred to the inside (space 221) of FFRM deposition chamber 217 by substrate transferring device 215.

In this example, in order to use single substrate type FFRM deposition chamber 217 as film-forming apparatus 210, one semiconductor substrate 228 was set in FFRM deposition chamber 217 so that the film-forming surface (surface 228a) of semiconductor substrate 228 was turned downward.

Thereby, as shown in FIG. 15, in FFRM deposition chamber 217, back face 228b of semiconductor substrate 228 was brought into contact with substrate disposing surface 226a of heater 226 for heating a substrate, and surface 228a of semiconductor substrate 228 and bottom face 217a of FFRM deposition chamber 217 face each other through shower plate 231.

The transmission of heat of the heater 226 for heating a substrate to FFRM deposition chamber 217 was prevented by providing a heat insulator or circulating device (not shown) for cooling water, or the like between heater 226 for heating a substrate and FFRM deposition chamber 217.

Then, liquefied carbon dioxide was prepared as a solvent (liquid) for dissolving the FFRM. A monomer and polymerization initiator serving as the FFRM of the polymer film were dissolved in the liquefied carbon dioxide. The concentration of the FFRM in the carbon dioxide is preferably in the range of from 5 to 50% in molar fraction.

For example, a monomer containing a vinyl group or an ethynyl group and having a cage structure such as biadamantan or diamantan can be used as the above-mentioned monomer. Although a commercially available product can be used as the above-mentioned monomer, a monomer synthesized by a known method may be used.

The polymerization initiator reacts with the vinyl group or the ethynyl group of the monomer (polymerization reaction), and thereby a final polymer film is formed. Examples of the polymerization reaction include radical polymerization, cationic polymerization, anionic polymerization, ring-opening polymerization and polycondensation. However, the polymerization reaction is not limited thereto.

The monomer and polymerization initiator to be used were dissolved in the liquid carbon dioxide in FFRM liquid adjuster 211 so as to have a prescribed concentration (for example, 30% in molar fraction).

Thereby, liquid carbon dioxide in which a monomer and polymerization initiator having a prescribed concentration are dissolved was produced as FFRM liquid 233. Hereinafter, “the liquid carbon dioxide in which a monomer and polymerization initiator having a prescribed concentration are dissolved” may be merely referred to as “FFRM liquid 233”.

Then, FFRM liquid 233 was introduced into FFRM deposition chamber 217 (space 221) through FFRM liquid feed hole 222, and the pressure of the carbon dioxide in FFRM deposition chamber 217 was adjusted to a prescribed value (6.5 MPa in this example). The temperature of the carbon dioxide at this time was set to 20° C. (a room temperature state).

At this time, FFRM liquid 233 introduced into FFRM deposition chamber 217 is fed to surface 228a of semiconductor substrate 228 through shower plate 231 from bottom face 217a side of FFRM deposition chamber 217 (a step shown in FIG. 16A).

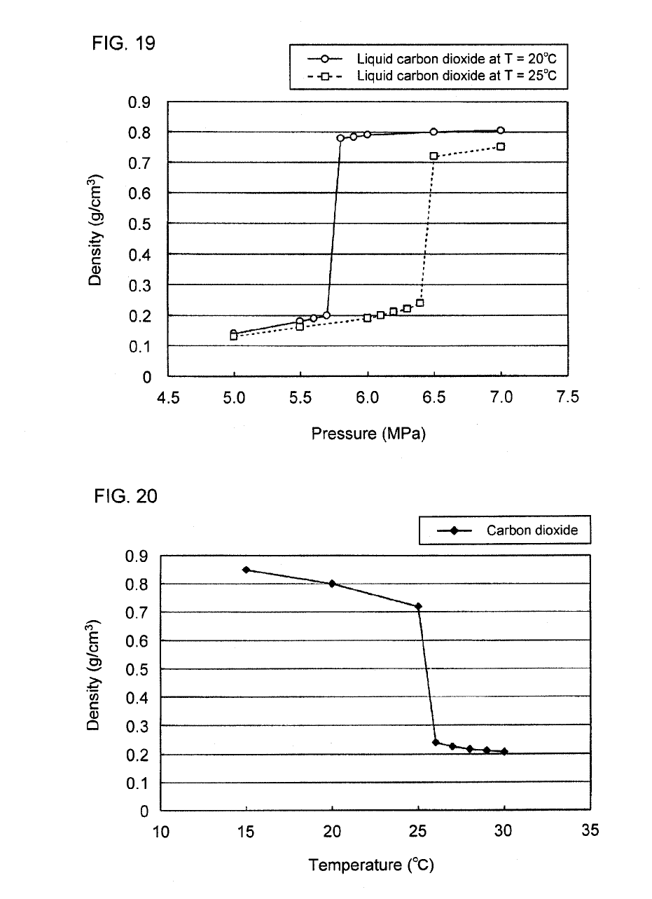

After the pressure of the carbon dioxide in FFRM deposition chamber 217 was then stabilized at a prescribed value (in this case, 6.5 MPa), the carbon dioxide was heated by heater 226 for heating a substrate so that the temperature of semiconductor substrate 228 was set to 30° C. The temperature dependence of the density of the carbon dioxide at this time is shown in FIG. 20.

With reference to FIG. 20, the liquid carbon dioxide was changed to a gas state when the temperature was about 25° C. or higher, which results in a drastic decrease in the density. In the phase change, a part of the monomer and polymerization initiator dissolved in the liquefied carbon dioxide adheres to surface 228a of semiconductor substrate 228 (a step shown in FIG. 16B).

The density change in accordance with the temperature change is produced in only the proximity of surface 228a of semiconductor substrate 228 heated by heater 226 for heating a substrate (see FIG. 15).

In film-forming apparatus 210 of this example, semiconductor substrate 228 is disposed on ceiling portion 217b of FFRM deposition chamber 217 so that the surface of semiconductor substrate 228 faces bottom face 217a of FFRM deposition chamber 217.

Thereby, as shown in FIG. 15, gaseous carbon dioxide B in the proximity of surface 228a of semiconductor substrate 228 and liquid carbon dioxide C in a location slightly separated from semiconductor substrate 228 (a region having a temperature equal to or lower than a phase change temperature) are phase-separated.

Actually, the density is gradually changed in boundary region D (see FIG. 15) between gaseous carbon dioxide B and liquid carbon dioxide C. Therefore, it is difficult to define a clear interface between gaseous carbon dioxide B and liquid carbon dioxide C. Since the deposition of FFRM 235 occurs only in a region of gaseous carbon dioxide B (a step shown in FIG. 16B), the unnecessary deposition of FFRM 235 in a portion other than surface 228a of semiconductor substrate 228 can be minimized.

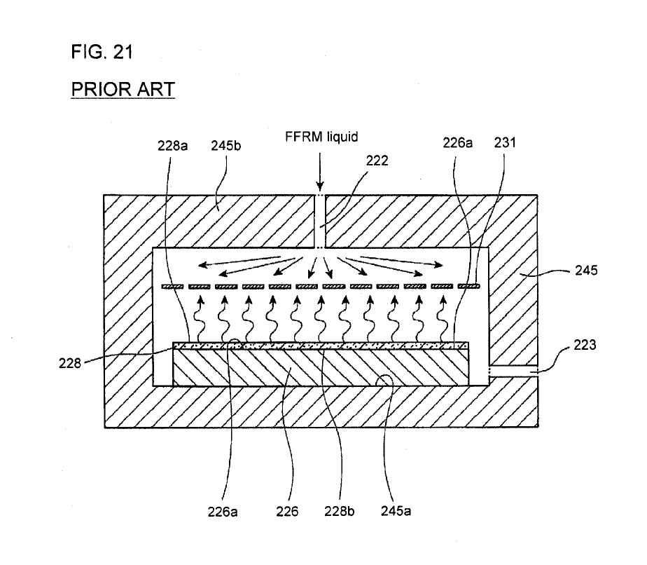

Herein, with reference to FIG. 21, for comparison with this example, there will be described a case in which a film is formed using a conventional constitution, specifically a conventional film-forming apparatus (for example, a conventional CVD apparatus) in which heater 226 for heating a substrate is set on bottom face 245a of FFRM deposition chamber 245. Semiconductor substrate 228 is placed on heater 226 for heating a substrate with the film-forming surface (surface 228a) of semiconductor substrate 228 turned upward.

FIG. 21 is a sectional view showing the schematic inside constitution of a FFRM deposition chamber provided in a film-forming apparatus according to a comparative example. In FIG. 21, the same constituent portions as those of the structure shown in FIG. 15 are provided with the same reference numerals.

In this case, since carbon dioxide B that was phase-changed to be in a gas state in the proximity of surface 228a of semiconductor substrate 228 had low density, carbon dioxide B rose toward ceiling portion 245b of FFRM deposition chamber 245. In accordance with the rising, heat also moved to ceiling portion 245b of FFRM deposition chamber 245. Therefore, it became difficult to maintain only the neighborhood of surface 228a of semiconductor substrate 228 at a high temperature.

As a result, FFRM 235 (see FIG. 16B) was deposited on not only surface 228a of semiconductor substrate 228 placed on substrate disposing surface 226a of heater 226 for heating a substrate but also on a region such as the surface of shower plate 231 disposed between ceiling portion 245b of FFRM deposition chamber 245 and semiconductor substrate 228.

Thereby, it was confirmed that the deposited FFRM adheres to the inner wall of the FFRM deposition chamber 41 in FFRM deposition chamber 245, and the peeled FFRM adheres also to the film-forming surface (surface 228a) of the semiconductor substrate to degrade morphology.

On the other hand, in this example, semiconductor substrate 228 is disposed close to ceiling portion 217b of FFRM deposition chamber 217 so that surface 228a (film-forming surface) of semiconductor substrate 228 is turned downward (see FIG. 15). Thereby, a region in which FFRM 235 is deposited can be limited to the proximity of surface 228a of semiconductor substrate 228.

In this example, FFRM 235 that adheres slightly to the portion other than surface 228a of semiconductor substrate 228 is redissolved when the liquid carbon dioxide is introduced during the next film-forming operation of semiconductor substrate 228. Thereby, FFRM 235 can be cleaned and reutilized.

In this example, since the FFRM is separately reacted using another chamber (reaction chamber 218) different from FFRM deposition chamber 217, the unreacted FFRM adheres to the inside of FFRM deposition chamber 217. Thereby, FFRM 235 can be cleaned and recovered.

Since the reaction step is not carried out in the step of depositing FFRM 235 on surface 228a of semiconductor substrate 228, particles caused by the reaction are not produced in FFRM deposition chamber 217.

Then, after adhesion of FFRM 235 (in this case, the monomer and the polymerization initiator) to surface 228a of semiconductor substrate 228 was completed, the heating by heater 226 for heating a substrate was shut down, and the liquefied carbon dioxide in which the monomer and the polymerization initiator were dissolved was discharged from FFRM deposition chamber 217, to reduce the pressure in FFRM deposition chamber 217 to atmospheric pressure.

Semiconductor substrate 228 having surface 228a to which the monomer and the polymerization initiator is adhered was then transferred to reaction chamber 218 by substrate transferring device 215.

Then, semiconductor substrate 228 was heated to a prescribed temperature (for example, 50 to 150° C.) in reaction chamber 218 to polymerize the monomer, thereby forming the polymer film on surface 228a of semiconductor substrate 228 (the step shown in FIG. 16C).

At this time, the inside of reaction chamber 218 is preferably under an inactive gas atmosphere (for example, nitrogen or argon) in order to suppress the inactivation of the polymerization initiator caused by oxygen.

However, the monomer and the polymerization initiator may be reacted under a usual air atmosphere depending on the kind of the monomer and polymerization initiator to be used.

At this time, a reagent (for example, AIBN: azobisisobutyronitrile) accelerating a reaction (in the case of this example, polymerization) may be further added from a reaction reagent feed system.

The polymer film formed by the film-forming method and the film-forming apparatus of this example had good surface morphology (a state in which no particulate projection or the like existed), and the adhesion (residue) of the polymer was not observed on the inner wall of reaction chamber 218 after forming the film.

That is, it was confirmed that the reaction of only FFRM 235 adhering to the surface 228a of semiconductor substrate 228 is allowed to proceed by using the film-forming method and the film-forming apparatus of the present invention, to form the polymer film, and the generation of the particles in FFRM deposition chamber 217 can be prevented.

What is claimed is:

1. A vaporizing and feed apparatus for vaporizing and feeding a solid film-forming raw material, the apparatus comprising:
a supercritical fluid feeding part for producing and feeding a supercritical fluid;
a supercritical fluid adjusting part for dissolving the solid film-forming raw material in the supercritical fluid by bringing the supercritical fluid fed from the supercritical fluid feeding part into contact with the solid film-forming raw material; and
a vaporizing part for phase-transitioning the supercritical fluid having the dissolved solid film-forming raw material to a gas, the solid film-forming raw material thereby being deposited in the gas, and for vaporizing the deposited solid film-forming raw material.

2. The vaporizing and feed apparatus according to claim 1, wherein the vaporizing part comprises a vaporizing chamber into which the supercritical fluid is introduced, and a heating device for heating an inside of the vaporizing chamber to a vapor temperature or higher of the solid film-forming raw material; and the inside of the vaporizing chamber is held at a pressure lower than a critical pressure of the supercritical fluid.

3. The vaporizing and feed apparatus according to claim 2, wherein the vaporizing part comprises a pressure adjusting device for adjusting a pressure of the supercritical fluid introduced to the vaporizing chamber.

4. The vaporizing and feed apparatus according to claim 1, wherein the supercritical fluid adjusting part comprises a high-pressure dissolving chamber accommodating the solid film-forming raw material, the supercritical fluid introduced into the high-pressure dissolving chamber; and an inside of the high-pressure dissolving chamber can be held at a temperature equal to or higher than a critical temperature of the supercritical fluid and a pressure equal to or higher than a critical pressure of the supercritical fluid.

5. The vaporizing and feed apparatus according to claim 1, wherein the supercritical fluid adjusting part comprises a column filled with the solid film-forming raw material and a filler inert to the supercritical fluid; and an inside of the column is held at a temperature equal to or higher than a critical temperature of the supercritical fluid and at a pressure equal to or higher than a critical pressure of the supercritical fluid.

6. The vaporizing and feed apparatus according to claim 1, wherein the supercritical fluid is carbon dioxide.

7. A vaporizing and feed method for vaporizing and feeding a solid film-forming raw material, comprising:
producing a supercritical fluid;
dissolving the solid film-forming raw material in the supercritical fluid by bringing the supercritical fluid into contact with the solid film-forming raw material; and
phase-transitioning the supercritical fluid having the dissolved solid film-forming raw material to a gas, to deposit the solid film-forming raw material in the gas, and vaporizing the deposited solid film-forming raw material.

8. The vaporizing and feed method according to claim 7, wherein the vaporizing the solid film-forming raw material comprises introducing the supercritical fluid into a space, an inside of the space being held at a pressure lower than a critical pressure of the supercritical fluid and said inside of the space being heated to a vapor temperature or higher of the solid film-forming raw material.

9. The vaporizing and feed method according to claim 7, wherein the dissolving the solid film-forming raw material comprises introducing the supercritical fluid into a space accommodating the solid film-forming raw material, an inside of the space being capable of being held at a temperature equal to or higher than a critical temperature of the supercritical fluid and at a pressure equal to or higher than a critical pressure of the supercritical fluid.

10. The vaporizing and feed method according to claim 7, wherein the dissolving the solid film-forming raw material comprises introducing the supercritical fluid into a space filled with the solid film-forming raw material and a filler inert to the supercritical fluid, an inside of the space being capable of being held at a temperature equal to or higher than a critical temperature of the supercritical fluid and at a pressure equal to or higher than a critical pressure of the supercritical fluid.

11. The vaporizing and feed method according to claim 7, wherein the supercritical fluid is carbon dioxide.

12. A film-forming method using a film-forming apparatus comprising a first chamber, a second chamber and medium feeding equipment, the method comprising:
accommodating a substrate in the first chamber so that a surface of the substrate that is to be film-formed is turned downward in a vertical direction;
feeding a medium to the first chamber from the medium feeding equipment in a state in which the medium is in a supercritical state, and is set to a temperature equal to or higher than a critical temperature and lower than a film-forming reaction temperature;
mixing a film-forming raw material with the supercritical medium fed to the first chamber after increasing a temperature of the substrate to a temperature or higher at which a film-forming reaction is produced; and
reducing a pressure in the first chamber to a pressure lower than the critical pressure of the medium by communicating the first chamber with the second chamber, simultaneously with shutting down the heating of the substrate and the feeding of the medium to the first chamber, after a film having a prescribed thickness is formed on the surface to be film-formed.

13. The film-forming method according to claim 12, wherein the inside of the first chamber is held in a pressure state higher than atmospheric pressure; and a pressure in the second chamber is set to an atmospheric pressure state, before the step of reducing the pressure.

14. The film-forming method according to claim 12, comprising:
refeeding the medium having the temperature equal to or higher than the critical temperature and lower than the film-forming reaction temperature to the first chamber after the temperature of the substrate is decreased to a temperature lower than the temperature at which the film-forming reaction is produced; and
recovering the media fed to the first chamber through the second chamber.

15. The film-forming method according to claim 12, wherein carbon dioxide is used as the medium.

16. The film-forming method according to claim 12, wherein water is used as the medium; and the mixing the film-forming raw material comprises holding the pressure in the first chamber at 22 MPa or higher in.

17. The film-forming method according to claim 12, wherein an oxide silicon film is formed using a TEOS gas and an oxygen gas as the film-forming raw material.

18. The film-forming method according to claim 12, wherein the film-forming raw material comprises a metal chelate compound; and a film containing as a component, metal contained in the metal chelate compound, is formed on the substrate.
